(19) United States
(12) Patent Application Publication
(10) Pub. No.: US 2026/0013201 A1
(43) Pub. Date: Jan. 8, 2026

(54) SEMICONDUCTOR DEVICE AND SEMICONDUCTOR DEVICE PRODUCTION METHOD

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/325,873

(22) Filed: Sep. 11, 2025

Related U.S. Application Data
(63) Continuation of application No. PCT/JP2024/007383, filed on Feb. 28, 2024.

(30) Foreign Application Priority Data
Mar. 20, 2023 (JP) 2023-044003

(51) Int. Cl. H10D 64/27; H10D 30/66; H10D 64/01

(52) U.S. Cl. CPC H10D 64/518; H10D 30/66; H10D 64/01

(57) ABSTRACT

Provided is a semiconductor device that includes a chip with a principal surface, on which a gate electrode is formed. An interlayer film covers the gate electrode, and an opening is formed in the film, laterally separated from the gate electrode's side portion. This opening exposes part of the principal surface as a contact surface. A front surface electrode is formed on the interlayer film and connects mechanically and electrically to the contact surface. The interlayer film comprises an insulating upper portion in contact with the gate electrode's top, an insulating side portion along its side, and an insulating corner portion along its corner. The thickness of the interlayer film at the corner portion is greater than at least one of the thicknesses at the upper or side portions. This structure enhances insulation and mechanical stability while allowing efficient electrical contact.

### CROSS-REFERENCE TO RELATED APPLICATIONS

The present application is a continuation application of PCT Application No. PCT/JP2024/007383, filed on Feb. 28, 2024, which claims priority to Japanese Patent Application No. 2023-044003, filed on Mar. 20, 2023, in the Japan Patent Office, and the entire disclosure of these applications are incorporated herein by reference.

### TECHNICAL FIELD

The present disclosure relates to a semiconductor device and a manufacturing method therefor.

### BACKGROUND ART

Japanese Patent Application Publication No. 2015-207588 discloses an SiC semiconductor device including a plurality of p-type body regions formed on a front surface portion of an n⁻ type SiC semiconductor layer, each of the p-type body regions constituting a unit cell, an n-type source region formed inside the p-type body region, a gate electrode facing the p-type body region through a gate insulating film, an n⁺ type drain region and a p⁺ type collector region formed adjacent to each other on a rear surface portion of the SiC semiconductor layer, and an n⁻ type drift region between the p-type body region and the n⁺ type drain region, in which the p⁺ type collector region is formed such as to cover a region including at least two unit cells in an X-axis along a front surface of the SiC semiconductor layer.

### BRIEF DESCRIPTION OF THE DRAWINGS

FIG. 1 is a plan view illustrating a semiconductor device according to one preferred embodiment.

FIG. 2 is a cross-sectional view taken along line II-II shown in FIG. 1.

FIG. 3 is a plan view illustrating a layout example of a first principal surface.

FIG. 4 is an enlarged plan view illustrating a main portion of the first principal surface.

FIG. 5 is an enlarged plan view illustrating a further main portion of the first principal surface.

FIG. 6 is a cross-sectional view taken along line VI-VI shown in FIG. 5.

FIG. 7 is an enlarged cross-sectional view illustrating a main portion of FIG. 6.

FIG. 8 is a cross-sectional view taken along line VIII-VIII shown in FIG. 5.

FIG. 9 is an enlarged cross-sectional view illustrating a main portion of FIG. 8.

FIG. 10 is an enlarged cross-sectional view illustrating a main portion of FIG. 7.

FIG. 11 is a schematic view illustrating a wafer.

FIGS. 12A to 12M are cross-sectional views illustrating a method for manufacturing the semiconductor device.

FIG. 13 is a cross-sectional view illustrating a first modification example of a gate electrode.

FIGS. 14A and 14B are views illustrating a step related to the formation of the gate electrode in FIG. 13.

FIG. 15 is a cross-sectional view illustrating a second modification example of the gate electrode.

FIGS. 16A and 16B are views illustrating a step related to the formation of the gate electrode in FIG. 15.

### DESCRIPTION OF EMBODIMENTS

Hereinafter, preferred embodiments shall be described in detail with reference to attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially” is used in this description, the wording includes a numerical value (mode) equal to a numerical value (mode) of a comparison target and also includes numerical errors (mode errors) in a range of ±10% on a basis of the numerical value (mode) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

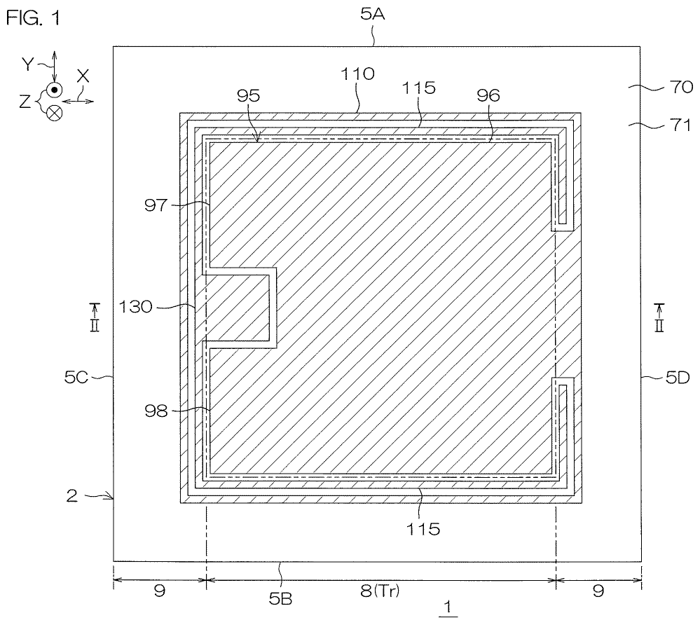

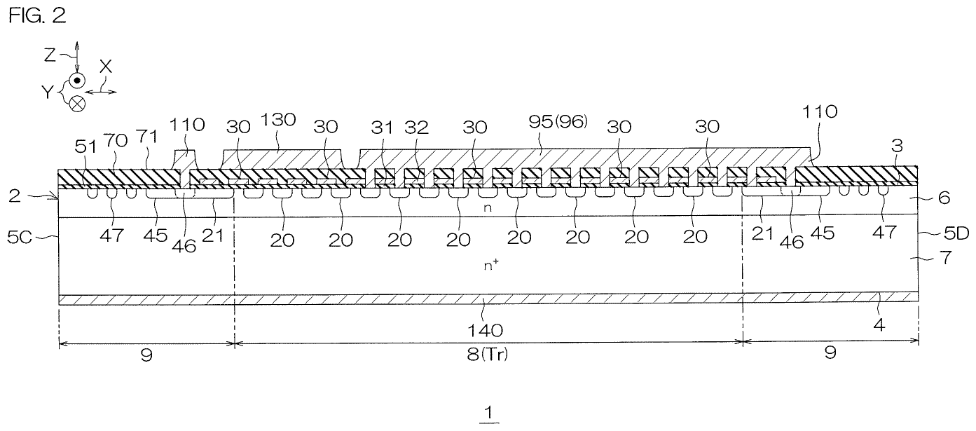

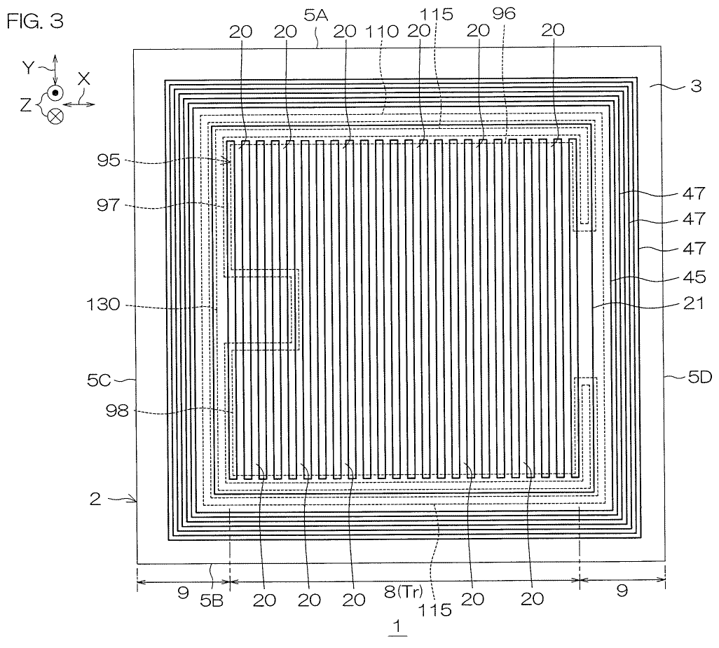

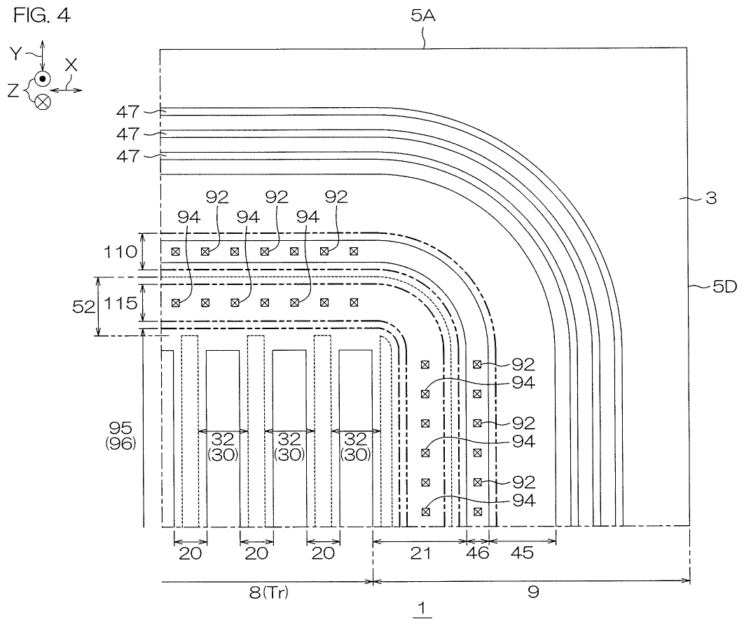

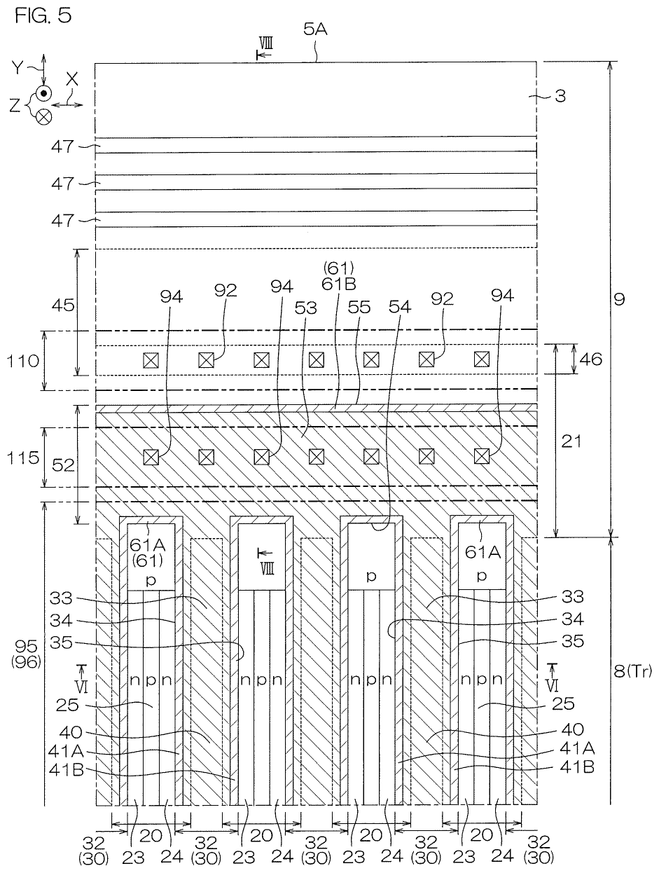

FIG. 1 is a plan view illustrating a semiconductor device 1 according to one preferred embodiment. FIG. 2 is a cross-sectional view taken along line II-II shown in FIG. 1. FIG. 3 is a plan view illustrating a layout example of a first principal surface 3. FIG. 4 is an enlarged plan view illustrating a main portion of the first principal surface 3. FIG. 5 is an enlarged plan view illustrating a further main portion of the first principal surface 3.

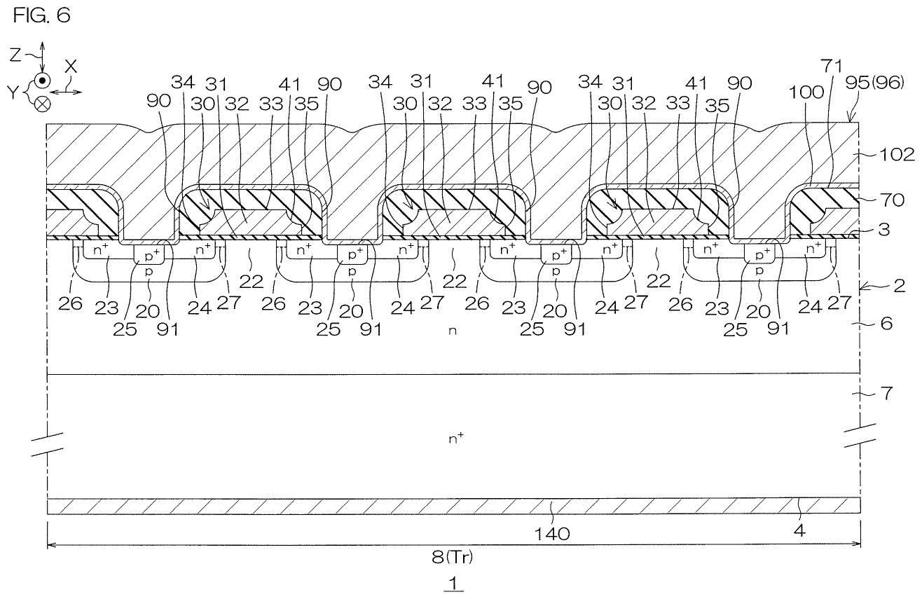

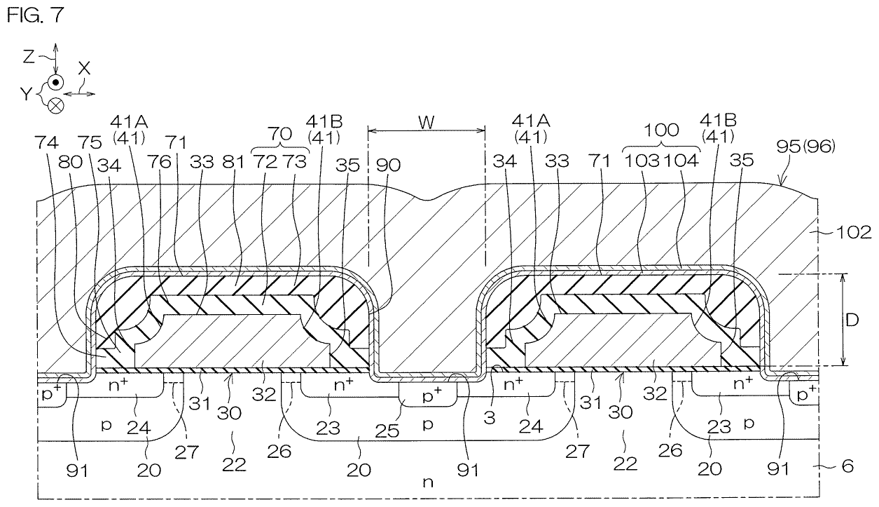

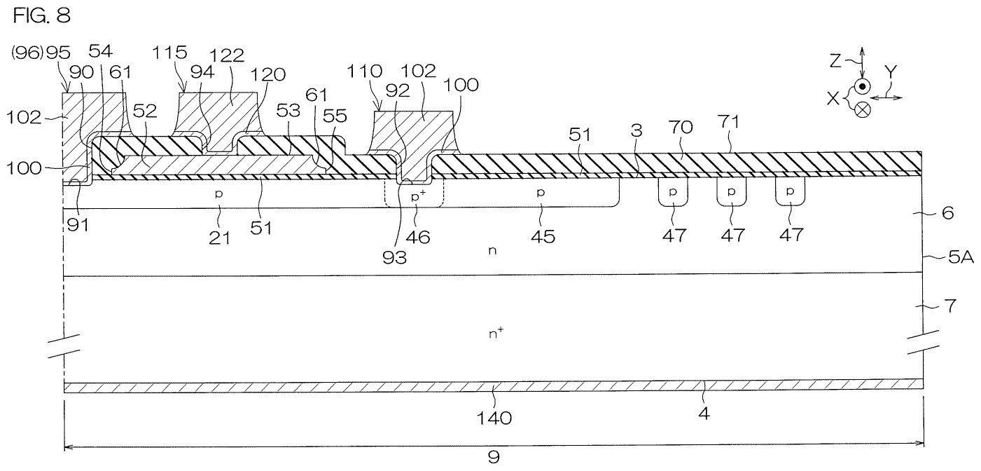

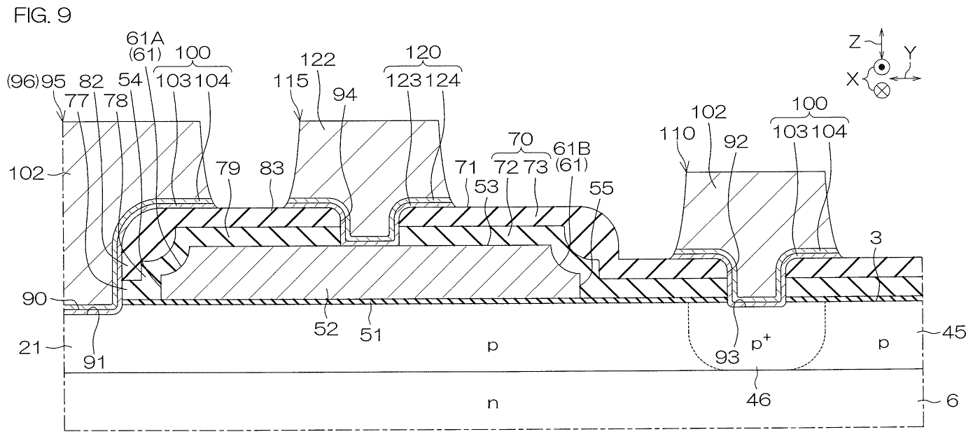

FIG. 6 is a cross-sectional view taken along line VI-VI shown in FIG. 5. FIG. 7 is an enlarged cross-sectional view illustrating a main portion of FIG. 6. FIG. 8 is a cross-sectional view taken along line VIII-VIII shown in FIG. 5. FIG. 9 is an enlarged cross-sectional view illustrating a main portion of FIG. 8.

Referring to FIGS. 1 to 9, the semiconductor device 1 is a semiconductor switching device having an insulated gate transistor structure Tr as an example of a device structure. The transistor structure Tr has a vertical structure. The semiconductor device 1 is an SiC semiconductor device having a chip 2 containing an SiC monocrystal. The chip 2 may be referred to as an “SiC chip” or as a “semiconductor chip.”

In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has the first principal surface 3 on one side, a second principal surface 4 on another side, and first to fourth side surfaces 5A to 5D connecting the first principal surface 3 and the second principal surface 4. In plan view as viewed from a vertical direction Z (hereinafter referred to simply as “plan view”), the first principal surface 3 and the second principal surface 4 are each formed in a quadrangular shape. The vertical direction Z is also a thickness direction of the chip 2 and a normal direction to the first principal surface 3 (second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane ((0001) plane) of the SiC monocrystal and the second principal surface 4 is formed by a carbon plane ((000-1) plane) of the SiC monocrystal.

The first side surface 5A and the second side surface 5B extend in a first direction X along the first principal surface 3 and face each other in a second direction Y intersecting the first direction X along the first principal surface 3. Specifically, the second direction Y is orthogonal to the first direction X. The third side surface 5C and the fourth side surface 5D extend in the second direction Y and face each other in the first direction X.

In the following description, one side in the first direction X means the third side surface 5C side, and the other side in the first direction X means the fourth side surface 5D side. Also, one side in the second direction Y means the first side surface 5A side, and the other side in the second direction Y means the second side surface 5B side. In this embodiment, the first direction X is an m-axis direction ([1-100] direction) of the SiC monocrystal and the second direction Y is an a-axis direction ([11-20] direction) of the SiC monocrystal. As a matter of course, the first direction X may instead be the a-axis direction of the SiC monocrystal and the second direction Y may instead be the m-axis direction of the SiC monocrystal.

The chip 2 (the first principal surface 3 and the second principal surface 4) has an off angle inclined at a predetermined angle in a predetermined off direction with respect to the c-plane of the SiC monocrystal. That is, a c-axis ((0001) axis) of the SiC monocrystal is inclined by just the off angle toward the off direction from the vertical axis. Also, the c-plane of the SiC monocrystal is inclined by just the off angle with respect to the horizontal plane.

The off direction is preferably the a-axis direction (that is, the second direction Y) of the SiC monocrystal. The off angle may exceed 0° and be 10° or less. The off angle may have a value belonging to at least one range among exceeding 0° and being 1° or less, being 1° or more and 2.5° or less, being 2.5° or more and 5° or less, being 5° or more and 7.5° or less, and being 7.5° or more and 10° or less.

The off angle is preferably 5° or less. The off angle is particularly preferably 2° or more and 4.5° or less. The off angle is typically set in a range of 4°+0.1°. This description does not exclude an embodiment in which the off angle is 0° (that is, an embodiment in which the first principal surface 3 is a just surface with respect to the c-plane).

The semiconductor device 1 includes a first semiconductor region 6 of the n-type that is formed in a region (surface layer portion) inside the chip 2 at the first principal surface 3 side. The first semiconductor region 6 may be referred to as a “drift region,” a “drain drift region,” a “drain region,” etc. A drain potential as a high potential (first potential) is applied to the first semiconductor region 6. The first semiconductor region 6 is formed in a layer shape extending along the first principal surface 3 and is exposed from the first principal surface 3 and the first to fourth side surfaces 5A to 5D. In this embodiment, the first semiconductor region 6 consists of an epitaxial layer (specifically, an SiC epitaxial layer).

The semiconductor device 1 includes a second semiconductor region 7 of the n-type that is formed in a region (surface layer portion) inside the chip 2 at the second principal surface 4 side. A drain potential is applied to the second semiconductor region 7. The second semiconductor region 7 may be referred to as a “drain region,” etc. The second semiconductor region 7 has an n-type impurity concentration higher than that of the first semiconductor region 6 and is electrically connected to the first semiconductor region 6 inside the chip 2.

The second semiconductor region 7 is formed in a layer shape extending along the second principal surface 4 and is exposed from the second principal surface 4 and the first to fourth side surfaces 5A to 5D. In this embodiment, the second semiconductor region 7 consists of a semiconductor substrate (specifically, an SiC substrate). That is, the chip 2 has a laminated structure including the semiconductor substrate and the epitaxial layer. The second semiconductor region 7 has a thickness larger than the thickness of the first semiconductor region 6.

The semiconductor device 1 includes an active region 8 that is set in the chip 2. The active region 8 is a region that includes a device structure (transistor structure Tr) and in which an output current (drain current) is generated. The active region 8 is set in an inner portion of the chip 2 at intervals from peripheral edges (the first to fourth side surfaces 5A to 5D) of the chip 2 in plan view. The active region 8 is set in a polygonal shape (in this embodiment, a quadrangular shape) having four sides parallel to the peripheral edges of the chip 2 in plan view. A plane area of the active region 8 is preferably 50% or more and 90% or less of the plane area of the first principal surface 3.

The semiconductor device 1 includes an outer peripheral region 9 that, in the chip 2, is set outside the active region 8. The outer peripheral region 9 is provided in a region between the peripheral edges of the chip 2 and the active region 8 in plan view. The outer peripheral region 9 extends in a band shape along the active region 8 and is set to a polygonal annular shape (in this embodiment, a quadrangular annular shape) that surrounds the active region 8 in plan view.

The semiconductor device 1 includes a plurality of p-type body regions 20 formed in a surface layer portion of the first principal surface 3 in the active region 8. A source potential as a low potential (second potential) different from a high potential (first potential) is applied to the plurality of body regions 20. The plurality of body regions 20 are arranged at intervals in the first direction X, and each formed in a band shape extending in the second direction Y. That is, the plurality of body regions 20 are arranged in a stripe shape extending in the second direction Y.

The plurality of body regions 20 are formed at intervals from a bottom portion of the first semiconductor region 6 toward the first principal surface 3, and face the second semiconductor region 7 across a part of the first semiconductor region 6. The plurality of body regions 20 are preferably formed at intervals from an intermediate portion of the first semiconductor region 6 toward the first principal surface 3. The plurality of body regions 20 are exposed from the first principal surface 3.

The semiconductor device 1 includes a p-type outer body region 21 formed in the surface layer portion of the first principal surface 3 in the outer peripheral region 9. The outer body region 21 preferably has a p-type impurity concentration substantially equal to the p-type impurity concentration of the body region 20. As a matter of course, the p-type impurity concentration of the outer body region 21 may be less than the p-type impurity concentration of the body region 20, or may be higher than the p-type impurity concentration of the body region 20.

The outer body region 21 is formed at intervals from the peripheral edges (the first to fourth side surfaces 5A to 5D) of the first principal surface 3 toward the active region 8, and extends in a band shape along the active region 8. The outer body region 21 has a portion extending in a band shape in the first direction X and a portion extending in a band shape in the second direction Y in plan view, and demarcates the active region 8 from a plurality of directions.

In this embodiment, the outer body region 21 surrounds the active region 8 in plan view and is demarcated in a polygonal annular shape (in this embodiment, a quadrangular annular shape) having four sides parallel to the peripheral edges of the first principal surface 3. That is, the outer body region 21 forms a boundary portion between the active region 8 and the outer peripheral region 9. The outer body region 21 may have an edge portion connecting the portion extending in the first direction X and the portion extending in the second direction Y in plan view in an arcuate shape (preferably a quadrant arcuate shape) (see FIG. 4).

The outer body region 21 has an inner edge portion on the active region 8 side and an outer edge portion on the peripheral edge side of the first principal surface 3. The inner edge portion of the outer body region 21 is connected to the plurality of body regions 20 in the portion extending in the first direction X. Thus, the outer body region 21 is fixed at the same potential as the plurality of body regions 20.

The outer body region 21 preferably has a width larger than the width of the body region 20. The width of the body region 20 is a width in a direction orthogonal to an extension direction (that is, the first direction X). The width of the outer body region 21 is a width in a direction orthogonal to the extension direction. As a matter of course, the width of the outer body region 21 may be substantially equal to the width of the body region 20, or may be less than the thickness of the body region 20.

The ratio of the width of the outer body region 21 to the width of the body region 20 may be 10 or more and 50 or less. The width ratio is preferably 20 or more and 40 or less.

The outer body region 21 is formed at an interval from the bottom portion of the first semiconductor region 6 toward the first principal surface 3, and faces the second semiconductor region 7 across a part of the first semiconductor region 6. The outer body region 21 is preferably formed at an interval from the intermediate portion of the first semiconductor region 6 toward the first principal surface 3. The outer body region 21 is exposed from the first principal surface 3.

The outer body region 21 preferably has a thickness (depth) substantially equal to the thickness (depth) of the body region 20. As a matter of course, the thickness of the outer body region 21 may be less than the thickness of the body region 20, or may be larger than the thickness of the body region 20.

The semiconductor device 1 includes a plurality of n-type surface layer drift regions 22 formed in the surface layer portion of the first principal surface 3. In this embodiment, each of the plurality of surface layer drift regions 22 is constituted of a part of the first semiconductor region 6. As a matter of course, the plurality of surface layer drift regions 22 may have an n-type impurity concentration higher than the n-type impurity concentration of the first semiconductor region 6, or may have an n-type impurity concentration lower than the n-type impurity concentration of the first semiconductor region 6.

The plurality of surface layer drift regions 22 are each demarcated in a region between the plurality of body regions 20 adjacent to each other in the first direction X. Specifically, the plurality of surface layer drift regions 22 are each demarcated by the plurality of body regions 20 and the outer body region 21 in the surface layer portion of the first principal surface 3. The plurality of surface layer drift regions 22 are arranged at intervals in the first direction X, and each formed in a band shape extending in the second direction Y. That is, the plurality of surface layer drift regions 22 are formed in a stripe shape extending in the second direction Y.

The semiconductor device 1 includes a plurality of n-type source regions 23 and 24 formed in surface layer portions of the plurality of body regions 20, respectively. The plurality of source regions 23 and 24 have an n-type impurity concentration higher than the n-type impurity concentration of the first semiconductor region 6. A source potential is applied to the plurality of source regions 23 and 24.

The plurality of source regions 23 and 24 include a first source region 23 positioned on one side in the first direction X and a second source region 24 positioned on the other side in the first direction X in the surface layer portion of each body region 20. In this embodiment, in the first direction X, one first source region 23 is formed on one end side of the body region 20, and one second source region 24 is formed on the other end side of the body region 20.

The first source region 23 is formed at an interval from one end of the body region 20 toward the other end, and extends in a band shape along the extension direction of the body region 20. The first source region 23 is formed at an interval from the outer body region 21 in the second direction Y. That is, the first source region 23 is not formed in the outer body region 21. The first source region 23 is formed at an interval from a bottom portion of the body region 20 toward the first principal surface 3, and faces the first semiconductor region 6 across a part of the body region 20.

The second source region 24 is formed at an interval from the first source region 23 toward the other end of the body region 20. The second source region 24 is formed at an interval from the other end of the body region 20 toward the one end, and extends in a band shape along the extension direction of the body region 20. The second source region 24 is formed at an interval from the outer body region 21 in the second direction Y. That is, the second source region 24 is not formed in the outer body region 21. The second source region 24 is formed at an interval from the bottom portion of the body region 20 toward the first principal surface 3, and faces the first semiconductor region 6 across a part of the body region 20.

When the plurality of first source regions 23 are formed in one body region 20, the plurality of first source regions 23 may be formed at intervals in the extension direction of the body region 20. In this case, each of the first source regions 23 may be formed in a band shape extending in the second direction Y. Similarly, when the plurality of second source regions 24 are formed in one body region 20, the plurality of second source regions 24 may be formed at intervals in the extension direction of the body region 20. In this case, each of the second source regions 24 may be formed in a band shape extending in the second direction Y.

The semiconductor device 1 includes a plurality of p-type contact regions 25 each formed in the surface layer portion of the plurality of body regions 20 in the active region 8. The contact region 25 may be referred to as a “back gate region.” A source potential is applied to the plurality of contact regions 25. The contact region 25 has a p-type impurity concentration higher than the p-type impurity concentration of the body region 20.

In this embodiment, one contact region 25 is interposed in a region between the first source region 23 and the second source region 24 in the surface layer portion of the corresponding body region 20. The contact region 25 extends in a band shape along the extension direction of the body region 20 (the source regions 23 and 24). The contact region 25 is formed at an interval from the outer body region 21 in the second direction Y. That is, the contact region 25 is not formed in the outer body region 21. The contact region 25 is formed at an interval from the bottom portion of the body region 20 toward the first principal surface 3, and faces the first semiconductor region 6 across a part of the body region 20.

When the plurality of contact regions 25 are formed in one body region 20, the plurality of contact regions 25 may be formed at intervals in the extension direction of the body region 20. In this case, each of the contact regions 25 may be formed in a band shape extending in the second direction Y.

The semiconductor device 1 includes a plurality of p-type channel regions 26 and 27 formed in the surface layer portion of the first principal surface 3. The plurality of channel regions 26 and 27 are demarcated in regions between end portions of the plurality of body regions 20 (the plurality of surface layer drift regions 22) and peripheral edges of the plurality of source regions 23 and 24, respectively, in the surface layer portions of the plurality of body regions 20. In this embodiment, the plurality of channel regions 26 and 27 are arranged at intervals in the first direction X and are each formed in a band shape extending in the second direction Y. That is, the plurality of channel regions 26 and 27 are arranged in a stripe shape extending in the second direction Y.

The plurality of channel regions 26 and 27 include a plurality of first channel regions 26 and a plurality of second channel regions 27. The plurality of first channel regions 26 are demarcated in regions between one ends (surface layer drift region 22) of the plurality of body regions 20 and the plurality of first source regions 23, respectively, and form a current path extending in a horizontal direction. The plurality of second channel regions 27 are demarcated in regions between the other ends (surface layer drift region 22) of the plurality of body regions 20 and the plurality of second source regions 24, respectively, and form a current path extending in the horizontal direction.

The semiconductor device 1 includes a plurality of gate structures 30 of a planar electrode type disposed on the first principal surface 3 in the active region 8. The plurality of gate structures 30 are arranged at intervals in the first direction X, and each formed in a band shape extending in the second direction Y. That is, the plurality of gate structures 30 are arranged in a stripe shape extending in the second direction Y. The extension direction of the plurality of gate structures 30 coincides with the off direction of the SiC monocrystal.

Each gate structure 30 is disposed on at least one channel region 26 or 27. In this embodiment, each gate structure 30 is disposed such as to extend across two body regions 20 adjacent to each other across one surface layer drift region 22, and covers the plurality of channel regions 26 and 27. Specifically, each gate structure 30 is disposed such as to extend across the first source region 23 on one body region 20 side and the second source region 24 on the other body region 20 side, and covers the surface layer drift region 22, the first source region 23, the second source region 24, the first channel region 26, and the second channel region 27.

Hereinafter, a configuration of one gate structure 30 shall be described. The gate structure 30 has a laminated structure including an insulating film 31 and a gate electrode 32. The gate structure 30 does not have an insulating side wall structure (spacer) at a side of the gate electrode 32. The insulating film 31 may include at least one among a silicon oxide film, a silicon nitride film, and a silicon oxynitride film. In this embodiment, the insulating film 31 has a single layer structure constituted of the silicon oxide film. The insulating film 31 particularly preferably includes a silicon oxide film constituted of an oxide of the chip 2.

The insulating film 31 covers the first principal surface 3 in a film shape and is disposed on at least one channel region 26 or 27. In this embodiment, the insulating film 31 is disposed such as to extend across two body regions 20 adjacent to each other across one surface layer drift region 22, and covers the plurality of channel regions 26 and 27.

Specifically, the insulating film 31 is disposed such as to extend across the first source region 23 on one body region 20 side and the second source region 24 on the other body region 20 side, and covers the surface layer drift region 22, the first source region 23, the second source region 24, the first channel region 26, and the second channel region 27.

The insulating film 31 partially covers the first source region 23 at an interval from the contact region 25, and exposes a part of the first source region 23 and the contact region 25 from the first principal surface 3. The insulating film 31 partially covers the second source region 24 at an interval from the contact region 25, and exposes a part of the second source region 24 and the contact region 25 from the first principal surface 3.

The thickness of the insulating film 31 may be 10 nm or more and 150 nm or less. The thickness of the insulating film 31 may have a value belonging to at least one range among 10 nm or more and 25 nm or less, 25 nm or more and 50 nm or less, 50 nm or more and 75 nm or less, 75 nm or more and 100 nm or less, 100 nm or more and 125 nm or less, and 125 nm or more and 150 nm or less. The thickness of the insulating film 31 is preferably 25 nm or more and 75 nm or less.

The gate electrode 32 is disposed on the insulating film 31 and faces at least one channel region 26 or 27 across the insulating film 31. A gate potential as a control potential is applied to the gate electrode 32. The gate electrode 32 controls inversion and non-inversion of at least one channel region 26 or 27 in response to the gate potential.

The gate electrode 32 contains a semiconductor polycrystal having conductivity. The gate electrode 32 may contain either or both of a p-type conductive polysilicon and an n-type conductive polysilicon. The conductivity type of the gate electrode 32 is adjusted according to the gate threshold voltage to be achieved. The gate electrode 32 may be referred to as a “polysilicon gate,” a “poly gate,” etc.

The gate electrode 32 is formed in a band shape extending in the second direction Y. That is, the extension direction of the gate electrode 32 coincides with the off direction of the SiC monocrystal. In this embodiment, the gate electrode 32 is formed at intervals inward from both end portions of the insulating film 31 in the first direction X, and exposes both end portions of the insulating film 31. The gate electrode 32 is disposed on the insulating film 31 such as to extend across two body regions 20 adjacent to each other across one surface layer drift region 22, and faces the plurality of channel regions 26 and 27 across the insulating film 31.

Specifically, the gate electrode 32 is disposed such as to extend across the first source region 23 on one body region 20 side and the second source region 24 on the other body region 20 side, and faces the surface layer drift region 22, the first source region 23, the second source region 24, the first channel region 26, and the second channel region 27 across the insulating film 31.

The gate electrode 32 includes an electrode upper portion 33, a first electrode side portion 34 on one side in the first direction X, and a second electrode side portion 35 on the other side in the first direction X. The electrode upper portion 33 extends along the insulating film 31 (first principal surface 3). The electrode upper portion 33 may extend substantially parallel to the insulating film 31 (first principal surface 3). The electrode upper portion 33 may be referred to as an electrode upper wall.

The first electrode side portion 34 is formed at an interval from one end portion of the insulating film 31 toward the other end portion in the first direction X, and extends in the vertical direction Z. The second electrode side portion 35 is formed at an interval from the other end portion of the insulating film 31 toward the one end portion in the first direction X, and extends in the vertical direction Z.

The first electrode side portion 34 and the second electrode side portion 35 may extend perpendicularly with respect to the insulating film 31. That is, the gate electrode 32 may be formed in a quadrangular shape (flat rectangular shape) in cross-sectional view. The first electrode side portion 34 and the second electrode side portion 35 may be inclined obliquely toward the electrode upper portion 33. That is, the gate electrode 32 may be formed in a tapered shape (preferably an isosceles trapezoidal shape) in cross-sectional view. The first electrode side portion 34 and the second electrode side portion 35 may be referred to as a first electrode side wall and a second electrode side wall, respectively.

A width of the gate structure 30 may be 1 μm or more and 10 μm or less. The width of the gate structure 30 is a width in a direction orthogonal to the extension direction (that is, the first direction X). The width of the gate structure 30 is preferably 1 μm or more and 5 μm or less.

A thickness of the gate structure 30 may be 0.1 μm or more and 2.0 μm or less. The thickness of the gate structure 30 is preferably 0.2 μm or more and 1.0 μm or less.

Referring to FIGS. 6 and 7, the gate electrode 32 includes an electrode corner portion 41 connecting the electrode upper portion 33 to the first electrode side portion 34 and the second electrode side portion 35. The electrode corner portion 41 is a portion formed by lacking a part of the material of the gate electrode 32. In this embodiment, the electrode corner portion 41 is formed by a recess portion curved toward an inner side of the gate electrode 32. As a result, the electrode upper portion 33 is partially formed on a front surface portion of each gate electrode 32 in plan view.

In plan view, the electrode upper portion 33 is formed at an interval inward from at least one of the first electrode side portion 34 and the second electrode side portion 35 of the gate electrode 32, and exposes at least one of a peripheral edge portion on the first electrode side portion 34 side and a peripheral edge portion on the second electrode side portion 35 side. In this embodiment, the electrode upper portion 33 is formed at intervals inward from both the first electrode side portion 34 and the second electrode side portion 35, and exposes both the peripheral edge portion on the first electrode side portion 34 side and the peripheral edge portion on the second electrode side portion 35 side in plan view.

The electrode upper portion 33 is formed in a band shape extending along the gate electrode 32 in plan view. That is, the extension direction of the electrode upper portion 33 coincides with the off direction of the SiC monocrystal. The electrode upper portion 33 faces one surface layer drift region 22 in a lamination direction. The electrode upper portion 33 may be formed at intervals from two body regions 20 adjacent to each other toward the surface layer drift region 22 in plan view, and may face only one surface layer drift region 22 in the lamination direction.

The electrode upper portion 33 may extend across two body regions 20 adjacent to each other across one surface layer drift region 22 in plan view. In this case, the electrode upper portion 33 may be formed at intervals toward the surface layer drift region 22 from the first source region 23 on one body region 20 side and the second source region 24 on the other body region 20 side, and may face the surface layer drift region 22, the first channel region 26, and the second channel region 27 in the lamination direction.

In this embodiment, the electrode upper portion 33 is formed such as to extend across the first source region 23 on the one body region 20 side and the second source region 24 on the other body region 20 side, and faces the surface layer drift region 22, the first source region 23, the second source region 24, the first channel region 26, and the second channel region 27 in the lamination direction.

In view of the responsiveness of the switching speed, the electrode upper portion 33 preferably faces either or both (preferably both) of the first channel region 26 and the second channel region 27. The electrode upper portion 33 preferably faces an entire region of the first channel region 26 in the lamination direction in cross-sectional view. The electrode upper portion 33 preferably faces an entire region of the second channel region 27 in the lamination direction in cross-sectional view.

The electrode corner portion 41 adopts various layouts according to the layout of the electrode upper portion 33. When the electrode upper portion 33 is formed at an interval inward from at least one of the first electrode side portion 34 and the second electrode side portion 35 of the gate electrode 32 in plan view, the electrode corner portion 41 is formed in a region on at least one side of the first electrode side portion 34 and the second electrode side portion 35.

In this embodiment, the electrode upper portion 33 is formed at intervals inward from both the first electrode side portion 34 and the second electrode side portion 35 of the gate electrode 32. Therefore, the electrode corner portion 41 has one electrode corner portion 41A demarcated in a region on the first electrode side portion 34 side with respect to the electrode upper portion 33 and the other electrode corner portion 41B demarcated in a region on the second electrode side portion 35 side with respect to the electrode upper portion 33 (see FIGS. 5 and 7).

The one electrode corner portion 41A is continuous from a peripheral edge portion on one side of the electrode upper portion 33 to the first electrode side portion 34. The one electrode corner portion 41A extends in a band shape in the second direction Y along the electrode upper portion 33. The other electrode corner portion 41B is continuous from the peripheral edge portion on the other side of the electrode upper portion 33 to the second electrode side portion 35. The other electrode corner portion 41B faces the one electrode corner portion 41A in the first direction X across the electrode upper portion 33, and extends in a band shape in the second direction Y along the electrode upper portion 33.

The one electrode corner portion 41A faces the first source region 23 in the lamination direction. The one electrode corner portion 41A may face only the first source region 23 in the lamination direction. The one electrode corner portion 41A may face the first source region 23 and the first channel region 26 in the lamination direction. The one electrode corner portion 41A may face the surface layer drift region 22, the first source region 23, and the first channel region 26 in the lamination direction.

In view of the responsiveness of the switching speed, it is preferable that the one electrode corner portion 41A is formed at an interval from the first channel region 26 toward the first electrode side portion 34 in plan view. That is, it is preferable that the one electrode corner portion 41A does not face the first channel region 26 in the lamination direction in cross-sectional view.

The other electrode corner portion 41B faces the second source region 24 in the lamination direction. The other electrode corner portion 41B may face only the second source region 24 in the lamination direction. The other electrode corner portion 41B may face the second source region 24 and the second channel region 27 in the lamination direction. The other electrode corner portion 41B may face the surface layer drift region 22, the second source region 24, and the second channel region 27 in the lamination direction.

In view of the responsiveness of the switching speed, it is preferable that the other electrode corner portion 41B is formed at an interval from the second channel region 27 toward the second electrode side portion 35 in plan view. That is, it is preferable that the other electrode corner portion 41B does not face the second channel region 27 in the lamination direction in cross-sectional view.

Referring to FIGS. 4, 5, and 8, the semiconductor device 1 includes a p-type terminal region 45 formed on the first principal surface 3 in the outer peripheral region 9. The terminal region 45, which may be referred to as a “well region,” a “terminal well region,” etc., may have a p-type impurity concentration substantially equal to the p-type impurity concentration of the outer body region 21. The p-type impurity concentration of the terminal region 45 may be higher than the p-type impurity concentration of the outer body region 21, or may be lower than the p-type impurity concentration of the outer body region 21.

The terminal region 45 is formed in a region between the peripheral edges of the first principal surface 3 and the outer body region 21 at intervals inward from the peripheral edges of the first principal surface 3. The terminal region 45 extends in a band shape along the outer body region 21 in plan view. The terminal region 45 has a portion extending in a band shape in the first direction X and a portion extending in a band shape in the second direction Y in plan view, and demarcates the active region 8 from a plurality of directions.

In this embodiment, the terminal region 45 surrounds the outer body region 21 in plan view, and is demarcated in a polygonal annular shape (a quadrangular annular shape in this embodiment) having four sides parallel to the peripheral edges of the first principal surface 3. The terminal region 45 may have an edge portion connecting the portion extending in the first direction X and the portion extending in the second direction Y in plan view in an arcuate shape (preferably a quadrant arcuate shape) (see FIG. 4).

The terminal region 45 is formed at an interval from the bottom portion of the first semiconductor region 6 toward the first principal surface 3, and faces the second semiconductor region 7 across a part of the first semiconductor region 6. The terminal region 45 is preferably formed at an interval from the intermediate portion of the first semiconductor region 6 toward the first principal surface 3. The terminal region 45 may have a thickness (depth) substantially equal to the thickness (depth) of the outer body region 21. The thickness of the terminal region 45 may be larger than the thickness of the outer body region 21, or may be smaller than the thickness of the outer body region 21.

The terminal region 45 has an inner edge portion on the active region 8 side and an outer edge portion on the peripheral edge side of the first principal surface 3. The inner edge portion of the terminal region 45 is connected to the outer edge portion of the outer body region 21. As a result, the terminal region 45 is fixed at the same potential as the outer body region 21, and is electrically connected to the plurality of body regions 20 through the outer body region 21. In this embodiment, the inner edge portion of the terminal region 45 is connected to the outer edge portion of the outer body region 21 over an entire circumference.

The terminal region 45 (inner edge portion) has an overlap region 46 overlapping the outer edge portion of the outer body region 21. The overlap region 46 is a high concentration region including the outer edge portion of the outer body region 21 and the inner edge portion of the terminal region 45. That is, the overlap region 46 includes both the p-type impurity of the outer body region 21 and the p-type impurity of the terminal region 45, and has a p-type impurity concentration higher than both the p-type impurity concentration of the outer body region 21 and the p-type impurity concentration of the terminal region 45.

The overlap region 46 extends in a band shape along the outer body region 21 in plan view. The overlap region 46 has a portion extending in a band shape in the first direction X and a portion extending in a band shape in the second direction Y in plan view, and demarcates the active region 8 from a plurality of directions. In this embodiment, the overlap region 46 is demarcated in a polygonal annular shape (a quadrangular annular shape in this embodiment) having four sides parallel to the peripheral edges of the first principal surface 3. A width of the overlap region 46 is preferably larger than the width of the body region 20. As a matter of course, the width of the overlap region 46 may be not more than the width of the body region 20.

The semiconductor device 1 may have a p-type well region (46) having a relatively high concentration instead of the overlap region 46. In this case, the well region (46) has a p-type impurity concentration higher than both the p-type impurity concentration of the outer body region 21 and the p-type impurity concentration of the terminal region 45. The well region (46) may be formed in either or both of a surface layer portion of the outer body region 21 and a surface layer portion of the terminal region 45.

The semiconductor device 1 includes at least one (preferably, two or more and twenty or less) p-type field region 47 formed in the surface layer portion of the first principal surface 3 in the outer peripheral region 9. The number of the plurality of field regions 47 is typically three or more and eight or less. In this embodiment, the semiconductor device 1 includes three field regions 47. The plurality of field regions 47 are formed in an electrically floating state, and relax an electric field in the chip 2 at a peripheral edge portion of the first principal surface 3. The number, interval, width, depth, p-type impurity concentration, etc., of the field regions 47 are arbitrary, and can take various values according to the electric field to be relaxed.

The field region 47 may have a p-type impurity concentration substantially equal to the p-type impurity concentration of the body region 20 (terminal region 45). The p-type impurity concentration of the field region 47 may be higher than the p-type impurity concentration of the body region 20 (terminal region 45), or may be lower than the p-type impurity concentration of the body region 20 (terminal region 45).

The plurality of field regions 47 are formed in a region between the peripheral edges of the first principal surface 3 and the active region 8 at intervals inward from the peripheral edges of the first principal surface 3. Specifically, the plurality of field regions 47 are formed in a region between the peripheral edges of the first principal surface 3 and the outer body region 21. More specifically, in a region between the peripheral edges of the first principal surface 3 and the terminal region 45, the plurality of field regions 47 are arranged at intervals from the terminal region 45 toward the peripheral edges of the first principal surface 3.

The plurality of field regions 47 are formed in a band shape extending along the active region 8 (terminal region 45) in plan view. Each of the plurality of field regions 47 has a portion extending in a band shape in the first direction X and a portion extending in a band shape in the second direction Y. In this embodiment, the plurality of field regions 47 are formed in a polygonal annular shape (in this embodiment, a quadrangular annular shape) surrounding the active region 8 (terminal region 45) in plan view. The plurality of field regions 47 may have an edge portion connecting the portion extending in the first direction X and the portion extending in the second direction Y in an arcuate shape (preferably a quadrant arcuate shape) (see FIG. 4).

The plurality of field regions 47 are formed at intervals from the bottom portion of the first semiconductor region 6 toward the first principal surface 3, and face the second semiconductor region 7 across a part of the first semiconductor region 6. The plurality of field regions 47 are preferably formed at intervals from the intermediate portion of the first semiconductor region 6 toward the first principal surface 3.

Referring to FIG. 8, the semiconductor device 1 includes an outer peripheral insulating film 51 covering the first principal surface 3 in the outer peripheral region 9. The outer peripheral insulating film 51 may include at least one among a silicon oxide film, a silicon nitride film, and a silicon oxynitride film. In this embodiment, the outer peripheral insulating film 51 has a single layer structure constituted of the silicon oxide film. The outer peripheral insulating film 51 particularly preferably includes a silicon oxide film constituted of an oxide of the chip 2. The outer peripheral insulating film 51 is preferably made of the same kind of insulating material as the insulating material of the insulating film 31. The outer peripheral insulating film 51 preferably has a thickness substantially equal to the thickness of the insulating film 31.

The outer peripheral insulating film 51 covers the first principal surface 3 in a film shape in the outer peripheral region 9. The outer peripheral insulating film 51 collectively covers the outer body region 21, the terminal region 45, and the plurality of field regions 47. The outer peripheral insulating film 51 is connected to the plurality of insulating films 31 on the active region 8 side. Specifically, the outer peripheral insulating film 51 is integrally formed with the plurality of insulating films 31, and forms one insulating film with the plurality of insulating films 31.

Referring to FIGS. 4, 5, and 8, the semiconductor device 1 includes a gate wiring 52 disposed on the first principal surface 3 in the outer peripheral region 9. The semiconductor device 1 does not have an insulating side wall structure (spacer) at a side of the gate wiring 52. The gate wiring 52 is selectively routed on the first principal surface 3 and has a portion extending in a direction different from the plurality of gate electrodes 32. The gate wiring 52 is connected to the plurality of gate electrodes 32, and applies a gate signal to the plurality of gate electrodes 32. The gate wiring 52 may be referred to as a “polysilicon gate wiring,” a “poly gate wiring,” a “second gate electrode,” etc.

The gate wiring 52 contains a semiconductor polycrystal having conductivity. The gate wiring 52 may contain cither or both of a p-type conductive polysilicon and an n-type conductive polysilicon. The gate wiring 52 preferably has the same conductivity type as the conductivity type of the gate electrode 32. The conductivity type of the gate wiring 52 is adjusted according to the conductivity type of the gate electrode 32.

The gate wiring 52 is disposed on the outer peripheral insulating film 51 in the outer peripheral region 9. Specifically, the gate wiring 52 is disposed on a portion of the outer peripheral insulating film 51 covering the outer body region 21, and faces the outer body region 21 across the outer peripheral insulating film 51. The gate wiring 52 is formed at intervals from the peripheral edges of the first principal surface 3 toward the active region 8, and extends in a band shape along the active region 8. The gate wiring 52 has a portion extending in a band shape in the first direction X and a portion extending in a band shape in the second direction Y in plan view, and demarcates the active region 8 from a plurality of directions.

In this embodiment, the gate wiring 52 surrounds the active region 8 in plan view, and is demarcated in a polygonal annular shape (a quadrangular annular shape in this embodiment) having four sides parallel to the peripheral edges of the first principal surface 3. The gate wiring 52 may have a shape with ends or an endless shape. In this embodiment, the gate wiring 52 extends in a band shape (an annular shape in this embodiment) along the outer body region 21 in plan view, and faces the outer body region 21 across the outer peripheral insulating film 51 in an entire region in the lamination direction. The gate wiring 52 may have an edge portion connecting the portion extending in the first direction X and the portion extending in the second direction Y in plan view in an arcuate shape (preferably a quadrant arcuate shape) (see FIG. 4).

The gate wiring 52 is formed to be narrower than the outer body region 21 in plan view, and is disposed above the outer body region 21 at intervals from the inner edge portion and the outer edge portion of the outer body region 21. That is, in this embodiment, the plurality of gate electrodes 32 are led out above the outer body region 21, and the gate wiring 52 is connected to the plurality of gate electrodes 32 above the outer body region 21.

A width of the gate wiring 52 is preferably larger than the width of the gate electrode 32. The width of the gate wiring 52 is a width in a direction orthogonal to the extension direction. As a matter of course, the width of the gate wiring 52 may be not more than the width of the gate electrode 32. The width of the gate wiring 52 may be larger than the width of the outer body region 21. A thickness of the gate wiring 52 is preferably substantially equal to the thickness of the gate electrode 32.

The gate wiring 52 includes a wiring upper portion 53, a first wiring side portion 54 on the inner edge side, and a second wiring side portion 55 on the outer edge side. The wiring upper portion 53 extends along the outer peripheral insulating film 51 (first principal surface 3). The wiring upper portion 53 may extend substantially parallel to the outer peripheral insulating film 51 (first principal surface 3). The wiring upper portion 53 may be referred to as a wiring upper wall. The first wiring side portion 54 extends in the vertical direction Z on the outer peripheral insulating film 51, and the second wiring side portion 55 extends in the vertical direction Z on the outer peripheral insulating film 51.

The first wiring side portion 54 is connected to the plurality of gate electrodes 32 (the first electrode side portion 34 and the second electrode side portion 35) in a portion extending in the first direction X. That is, the gate wiring 52 has a plurality of portions connected to the plurality of gate electrodes 32 in a T shape. Thus, the gate wiring 52 is fixed at the same potential as the plurality of gate electrodes 32.

The first wiring side portion 54 and the second wiring side portion 55 may extend perpendicularly with respect to the outer peripheral insulating film 51. That is, the gate wiring 52 may be formed in a quadrangular shape (flat rectangular shape) in cross-sectional view. The first wiring side portion 54 and the second wiring side portion 55 may be inclined obliquely toward the wiring upper portion 53. That is, the gate wiring 52 may be formed in a tapered shape (preferably an isosceles trapezoidal shape) in cross-sectional view. The first wiring side portion 54 and the second wiring side portion 55 may be referred to as a first wiring side wall and a second wiring side wall, respectively.

Referring to FIGS. 8 and 9, the gate wiring 52 includes a wiring corner portion 61 connecting the wiring upper portion 53 to the first wiring side portion 54 and the second wiring side portion 55. The wiring corner portion 61 is a portion formed by lacking a part of the material of the gate wiring 52. In this embodiment, the wiring corner portion 61 is formed by a recess portion curved toward an inner side of the gate wiring 52. Thus, the wiring upper portion 53 is partially formed on a front surface portion of each gate wiring 52 in plan view.

In plan view, the wiring upper portion 53 is formed at an interval inward from at least one of the first wiring side portion 54 and the second wiring side portion 55 of the gate wiring 52, and exposes at least one of a peripheral edge portion on the first wiring side portion 54 side and a peripheral edge portion on the second wiring side portion 55 side in the wiring upper portion 53. In this embodiment, the wiring upper portion 53 is formed at intervals inward from both the first wiring side portion 54 and the second wiring side portion 55, and exposes both the peripheral edge portion on the first wiring side portion 54 side and the peripheral edge portion on the second wiring side portion 55 side in the wiring upper portion 53.

The wiring upper portion 53 extends in a band shape along the gate wiring 52 in plan view and faces the outer body region 21 in the lamination direction. The wiring upper portion 53 has a portion extending in a band shape in the first direction X and a portion extending in a band shape in the second direction Y in plan view. In this embodiment, the wiring upper portion 53 surrounds the active region 8 in plan view and is demarcated in a polygonal annular shape (in this embodiment, a quadrangular annular shape) having four sides parallel to the peripheral edges of the first principal surface 3.

The wiring upper portion 53 may have a shape with ends or an endless shape. The wiring upper portion 53 may have an edge portion connecting the portion extending in the first direction X and the portion extending in the second direction Y in plan view in an arcuate shape (preferably a quadrant arcuate shape).

The wiring upper portion 53 is continuous with the plurality of electrode upper portions 33 at a connection portion of the plurality of gate electrodes 32 and the gate wiring 52. That is, the wiring upper portion 53 is integrally formed with the plurality of electrode upper portions 33 and has a plurality of portions connected to the plurality of electrode upper portions 33 in a T shape (see FIG. 5).

The wiring corner portion 61 adopts various layouts according to the layout of the wiring upper portion 53. When the wiring upper portion 53 is formed at an interval inward from at least one of the first wiring side portion 54 and the second wiring side portion 55 of the gate wiring 52, the wiring corner portion 61 is formed in a region on at least one side of the first wiring side portion 54 and the second wiring side portion 55 in the wiring upper portion 53.

In this embodiment, the wiring upper portion 53 is formed at intervals inward from both the first wiring side portion 54 and the second wiring side portion 55 of the gate wiring 52. Therefore, the wiring corner portion 61 has one wiring corner portion 61A demarcated in a region on the first wiring side portion 54 side with respect to the wiring upper portion 53 and the other wiring corner portion 61B demarcated in a region on the second wiring side portion 55 side with respect to the wiring upper portion 53 (see FIGS. 5 and 9).

The one wiring corner portion 61A is continuous from the peripheral edge portion on one side of the wiring upper portion 53 to the first wiring side portion 54 of the gate wiring 52. The one wiring corner portion 61A extends in a band shape along the wiring upper portion 53. The other wiring corner portion 61B is continuous from the other side of the wiring upper portion 53 to the second wiring side portion 55 of the gate wiring 52. The other wiring corner portion 61B faces the one wiring corner portion 61A across the wiring upper portion 53, and extends in a band shape along the wiring upper portion 53.

The wiring corner portion 61 (the one wiring corner portion 61A) is continuous with the plurality of electrode corner portions 41 at the connection portion of the plurality of gate electrodes 32 and the gate wiring 52. That is, the wiring corner portion 61 is integrally formed with the plurality of electrode corner portions 41. The wiring corner portion 61 has a plurality of portions connected to the plurality of electrode corner portions 41 in an L shape at connection corner portions of the plurality of gate electrodes 32 and the gate wirings 52 (see FIG. 5).

The semiconductor device 1 includes an insulating interlayer film 70 that covers the first principal surface 3. The interlayer film 70 may be referred to as an “interlayer insulating film,” an “intermediate insulating film,” etc. The interlayer film 70 collectively covers the active region 8 and the outer peripheral region 9 on the first principal surface 3.

The interlayer film 70 covers the plurality of gate structures 30 in the active region 8. The interlayer film 70 directly covers both the insulating film 31 and the gate electrode 32 with respect to each gate structure 30. That is, the interlayer film 70 has a portion that directly covers the electrode upper portion 33, the first electrode side portion 34, the second electrode side portion 35, and the electrode corner portion 41 of the gate electrode 32.

The interlayer film 70 collectively covers the outer body region 21, the terminal region 45, and the plurality of field regions 47 across the outer peripheral insulating film 51 in the outer peripheral region 9. The interlayer film 70 directly covers both the outer peripheral insulating film 51 and the gate wiring 52. That is, the interlayer film 70 has a portion that directly covers the wiring upper portion 53, the first wiring side portion 54, the second wiring side portion 55, and the wiring corner portion 61 of the gate wiring 52. In this embodiment, the interlayer film 70 is continuous with the first to fourth side surfaces 5A to 5D. The interlayer film 70 may be formed at intervals inward from the first to fourth side surfaces 5A to 5D and expose the peripheral edge portion (first semiconductor region 6) of the first principal surface 3.

In this embodiment, the interlayer film 70 has a laminated structure including a first oxide film 72 (first insulating film) and a second oxide film 73 (second insulating film) laminated in this order from the first principal surface 3 side. The first oxide film 72 has a single layer structure constituted of the silicon oxide film that is not doped with an impurity. The first oxide film 72 may be referred to as an NSG film (non-doped silicate glass film).

The first oxide film 72 collectively covers the active region 8 and the outer peripheral region 9. The first oxide film 72 collectively covers the plurality of gate structures 30 in the active region 8. The first oxide film 72 covers both the insulating film 31 and the gate electrode 32 in a film shape with respect to each gate structure 30.

The first oxide film 72 includes a first covering portion 74, a second covering portion 75, and a third covering portion 76. The first covering portion 74 extends in a film shape in the horizontal direction along the insulating film 31 (first principal surface 3) and has a portion in contact with the first electrode side portion 34 (second electrode side portion 35) of the gate electrode 32. In this embodiment, the first covering portion 74 (first oxide film 72) has a thickness less than the thickness of the gate electrode 32, and covers the insulating film 31 at an interval from a height position of the electrode upper portion 33 of the gate electrode 32 toward the insulating film 31.

The second covering portion 75 is led out from the first covering portion 74 toward the electrode upper portion 33 in the lamination direction, and directly covers the first electrode side portion 34 (second electrode side portion 35) and the electrode corner portion 41 in a film shape.

The third covering portion 76 is led out from the second covering portion 75 toward the electrode upper portion 33, and extends in a film shape in the horizontal direction along the electrode upper portion 33. The third covering portion 76 directly covers an entire region of the electrode upper portion 33 between the one electrode corner portion 41A and the other electrode corner portion 41B.

The first oxide film 72 collectively covers the outer body region 21, the terminal region 45, and the plurality of field regions 47 across the outer peripheral insulating film 51 in the outer peripheral region 9. The first oxide film 72 covers the gate wiring 52 in the outer peripheral region 9.

The first oxide film 72 includes a first wiring covering portion 77, a second wiring covering portion 78, and a third wiring covering portion 79. The first wiring covering portion 77 extends in a film shape in the horizontal direction along the outer peripheral insulating film 51 (first principal surface 3) and has a portion in contact with the first wiring side portion 54 (second wiring side portion 55) of the gate wiring 52. In this embodiment, the first wiring covering portion 77 (first oxide film 72) has a thickness less than the thickness of the gate wiring 52, and covers the outer peripheral insulating film 51 at an interval from a height position of the wiring upper portion 53 of the gate wiring 52 toward the outer peripheral insulating film 51.

The second wiring covering portion 78 is led out from the first wiring covering portion 77 toward the wiring upper portion 53 in the lamination direction, and directly covers the first electrode side portion 34 (second electrode side portion 35) and the wiring corner portion 61 in a film shape.

The third wiring covering portion 79 is led out from the second wiring covering portion 78 toward the wiring upper portion 53, and extends in a film shape in the horizontal direction along the wiring upper portion 53. The third wiring covering portion 79 directly covers an entire region of the wiring upper portion 53 between the one wiring corner portion 61A and the other wiring corner portion 61B.

The second oxide film 73 may have a single layer structure constituted of a silicon oxide film containing phosphorus or a laminated structure including a silicon oxide film containing phosphorus. The silicon oxide film containing phosphorus may contain boron. The silicon oxide film containing phosphorus may be referred to as a PSG film (phosphorus silicon glass film). The silicon oxide film containing both phosphorus and boron may be referred to as a BPSG film (boron phosphorus silicon glass film).

The second oxide film 73 may have a single layer structure constituted of a PSG film or a BPSG film laminated on the first oxide film 72. The second oxide film 73 may have a laminated structure including a PSG film laminated on the first oxide film 72 and a BPSG film laminated on the PSG film. The second oxide film 73 may have a laminated structure including a BPSG film laminated on the first oxide film 72 and a PSG film laminated on the BPSG film. In this embodiment, the second oxide film 73 has a single layer structure constituted of a PSG film as an example.

The second oxide film 73 covers the first oxide film 72 in a film shape, and collectively covers the active region 8 and the outer peripheral region 9 across the first oxide film 72. The second oxide film 73 collectively covers the plurality of gate structures 30 across the first oxide film 72 in the active region 8. Specifically, the second oxide film 73 covers both the insulating film 31 and the gate electrode 32 in a film shape across the first oxide film 72.

The second oxide film 73 includes a first upper covering portion 80 and a second upper covering portion 81. The first upper covering portion 80 covers the first covering portion 74 and the second covering portion 75 of the first oxide film 72. The first upper covering portion 80 covers the insulating film 31 across the first covering portion 74 in a portion positioned on the first covering portion 74.

The first upper covering portion 80 extends in a film shape in the lamination direction along the second covering portion 75 from above the first covering portion 74, and covers the first electrode side portion 34 (second electrode side portion 35) and the electrode corner portion 41 of the gate structure 30 across the second covering portion 75. That is, the first upper covering portion 80 has a portion covering the first electrode side portion 34 (second electrode side portion 35) and the electrode corner portion 41 across the second covering portion 75.

The second upper covering portion 81 covers the third covering portion 76 of the first oxide film 72. The second upper covering portion 81 extends in a film shape in the horizontal direction from the first upper covering portion 80 along the third covering portion 76, and covers the electrode upper portion 33 of the gate structure 30 across the third covering portion 76. The second upper covering portion 81 covers the entire region of the electrode upper portion 33 across the third covering portion 76 between the one electrode corner portion 41A and the other electrode corner portion 41B.

The second upper covering portion 81 has a portion covering the electrode upper portion 33 across the first oxide film 72 (third covering portion 76) and a portion covering the electrode corner portion 41 across the first oxide film 72 (second covering portion 75).

The second oxide film 73 collectively covers the outer body region 21, the terminal region 45, and the plurality of field regions 47 across the outer peripheral insulating film 51 and the first oxide film 72 in the outer peripheral region 9. The second oxide film 73 covers the gate wiring 52 across the first oxide film 72 in the outer peripheral region 9.

The second oxide film 73 includes a first upper wiring covering portion 82 and a second upper wiring covering portion 83. The first upper wiring covering portion 82 covers the first wiring covering portion 77 and the second wiring covering portion 78 of the first oxide film 72. The first upper wiring covering portion 82 covers the outer peripheral insulating film 51 across the first wiring covering portion 77 in a portion positioned on the first wiring covering portion 77.

The first upper wiring covering portion 82 extends in a film shape in the lamination direction along the second wiring covering portion 78 from above the first wiring covering portion 77, and covers the first wiring side portion 54 (second wiring side portion 55) and the wiring corner portion 61 across the second wiring covering portion 78. That is, the first upper wiring covering portion 82 has a portion covering the first wiring side portion 54 (second wiring side portion 55) and the wiring corner portion 61 across the second wiring covering portion 78.

The second upper wiring covering portion 83 covers the third wiring covering portion 79 of the first oxide film 72. The second upper wiring covering portion 83 extends in a film shape in the horizontal direction from the first upper wiring covering portion 82 along the third wiring covering portion 79, and covers the wiring upper portion 53 across the third wiring covering portion 79. The second upper wiring covering portion 83 covers the entire region of the wiring upper portion 53 across the third wiring covering portion 79 between the one wiring corner portion 61A and the other wiring corner portion 61B.

The second upper wiring covering portion 83 has a portion covering the wiring upper portion 53 across the first oxide film 72 (third wiring covering portion 79) and a portion covering the wiring corner portion 61 across the first oxide film 72 (second wiring covering portion 78).

The semiconductor device 1 includes a plurality of source openings 90 formed in the interlayer film 70 in the active region 8. The plurality of source openings 90 are formed in regions at sides of the plurality of gate electrodes 32 at intervals from the plurality of gate electrodes 32, respectively, and expose the first principal surface 3 (chip 2). Specifically, the plurality of source openings 90 are formed in regions between the plurality of gate electrodes 32, respectively, and penetrate through the insulating film 31 and the interlayer film 70.

The plurality of source openings 90 have wall surfaces penetrating through both the first oxide film 72 and the second oxide film 73 and demarcated by both the first oxide film 72 and the second oxide film 73. The plurality of source openings 90 respectively expose the corresponding plurality of source regions 23 and 24 and the contact region 25.

In this embodiment, the plurality of source openings 90 are formed at intervals in the first direction X, and are each formed in a band shape extending in the second direction Y. That is, the plurality of source openings 90 are formed in a stripe shape extending in the second direction Y. The plurality of source openings 90 are formed at intervals in the second direction Y from the gate wiring 52. That is, the plurality of source openings 90 are formed in a region surrounded by the plurality of gate electrodes 32 and the gate wiring 52.

The plurality of source openings 90 may be formed in a region between two gate structures 30 adjacent to each other in the first direction X. In this case, the plurality of source openings 90 may be formed at intervals in a line in the second direction Y. Furthermore, in this case, each source opening 90 may be formed in a quadrangular shape (square shape) in plan view, a rectangular shape extending in the first direction X, a rectangular shape extending in the second direction Y, a hexagonal shape, a circular shape, etc.

The source opening 90 may have a width W of 0.2 μm or more and 3 μm or less. The width W of the source opening 90 is preferably 0.3 μm or more and 1 μm or less. The source opening 90 may have a depth D of 0.2 μm or more and 2 μm or less. The depth D of the source opening 90 is preferably 0.5 μm or more and 1 μm or less.

The source opening 90 preferably has an aspect ratio D/W of 0.3 or more and 3 or less. The aspect ratio D/W is defined by the ratio of the depth D of the source opening 90 with respect to the width W of the source opening 90. The aspect ratio D/W is preferably 0.5 or more and 2 or less. The aspect ratio D/W is particularly preferably more than 1. According to this configuration, the plurality of gate structures 30 are arranged at a narrow pitch.

The semiconductor device 1 includes a plurality of source recesses 91 formed in portions of the first principal surface 3 exposed from the plurality of source openings 90, respectively. The semiconductor device 1 does not necessarily have to include the source recess 91. Therefore, a configuration without the source recess 91 may be adopted.

Each of the plurality of source recesses 91 has a planar shape matching the planar shape of the corresponding source opening 90, and is recessed from the first principal surface 3 toward the second principal surface 4. Each of the plurality of source recesses 91 is formed at an interval from the bottom portion of the corresponding body region 20 toward the first principal surface 3, and exposes the corresponding plurality of source regions 23 and 24 and the contact region 25. Specifically, the plurality of source recesses 91 are formed at an interval from bottom portions of the corresponding plurality of source regions 23 and 24 (contact region 25) toward the first principal surface 3.

The semiconductor device 1 includes at least one (in this embodiment, a plurality of) outer opening 92 formed in the interlayer film 70 in the outer peripheral region 9. The plurality of outer openings 92 are formed in a portion of the interlayer film 70 covering the terminal region 45. The plurality of outer openings 92 penetrate through the interlayer film 70 and expose the terminal region 45. In this embodiment, the plurality of outer openings 92 are formed in a portion of the interlayer film 70 covering the overlap region 46 of the terminal region 45 and expose the overlap region 46.

The plurality of outer openings 92 may expose the outer body region 21 instead of or in addition to the terminal region 45 (overlap region 46). The plurality of outer openings 92 have wall surfaces penetrating through both the first oxide film 72 and the second oxide film 73 and demarcated by both the first oxide film 72 and the second oxide film 73.

The plurality of outer openings 92 are formed at intervals along the terminal region 45 (overlap region 46) (see FIGS. 4 and 5). The plurality of outer openings 92 may be formed in a quadrangular shape (square shape), a rectangular shape, a hexagonal shape, a circular shape, etc., in plan view. The plurality of outer openings 92 may be formed in a band shape extending along the terminal region 45 (overlap region 46) in plan view. Similarly to the source opening 90, the outer opening 92 may have an aspect ratio D/W (preferably more than 1).

The semiconductor device 1 may have a single outer opening 92. The single outer opening 92 may be formed in a band shape extending along the terminal region 45 (overlap region 46). The single outer opening 92 may have a portion extending in a band shape in the first direction X and a portion extending in a band shape in the second direction Y in plan view.

The single outer opening 92 may be formed in a polygonal annular shape (a quadrangular annular shape in this embodiment) with or without ends having four sides parallel to the peripheral edges of the first principal surface 3. The single outer opening 92 may have an edge portion connecting the portion extending in the first direction X and the portion extending in the second direction Y in conformance to the terminal region 45 (overlap region 46) in plan view in an arcuate shape (preferably a quadrant arcuate shape).

The semiconductor device 1 includes a plurality of outer recesses 93 formed in portions of the first principal surface 3 exposed from the plurality of outer openings 92, respectively. The semiconductor device 1 does not necessarily have to include the outer recess 93. Therefore, a configuration without the outer recess 93 may be adopted.

Each of the plurality of outer recesses 93 has a planar shape matching the planar shape of the corresponding outer opening 92, and is recessed from the first principal surface 3 toward the second principal surface 4. The plurality of outer recesses 93 are formed at intervals from the bottom portion of the terminal region 45 (overlap region 46) toward the first principal surface 3 and expose the terminal region 45 (overlap region 46), respectively. When the single outer opening 92 is formed, a single outer recess 93 matching the planar shape of the single outer opening 92 is formed.

The semiconductor device 1 includes at least one (in this embodiment, a plurality of) gate opening 94 formed in the interlayer film 70 in the outer peripheral region 9. The plurality of gate openings 94 are formed in a portion of the interlayer film 70 covering the gate wiring 52. The plurality of gate openings 94 penetrate through the interlayer film 70 and expose the wiring upper portion 53 of the gate wiring 52.

Specifically, the plurality of gate openings 94 expose the wiring upper portion 53 of the gate wiring 52. More specifically, the plurality of gate openings 94 expose the wiring upper portion 53 at intervals inward from the wiring corner portion 61. The plurality of gate openings 94 expose only the wiring upper portion 53 and do not expose the wiring corner portion 61. As a matter of course, one or a plurality of gate openings 94 that expose the wiring corner portion 61 may be formed.

The plurality of gate openings 94 have wall surfaces penetrating through both the first oxide film 72 and the second oxide film 73 and demarcated by both the first oxide film 72 and the second oxide film 73.

The plurality of gate openings 94 are formed at intervals along the gate wiring 52 (wiring upper portion 53) (see FIGS. 4 and 5). The plurality of gate openings 94 may be formed in a quadrangular shape (square shape), a rectangular shape, a hexagonal shape, a circular shape, etc., in plan view. The plurality of gate openings 94 may be formed in a band shape extending along the gate wiring 52 in plan view. Similarly to the source opening 90, the gate opening 94 may have an aspect ratio D/W (preferably, more than 1).

The semiconductor device 1 may have a single gate opening 94. The single gate opening 94 may be formed in a band shape extending along the gate wiring 52. The single gate opening 94 may have a portion extending in a band shape in the first direction X and a portion extending in a band shape in the second direction Y in plan view.

The single gate opening 94 may be formed in a polygonal annular shape (a quadrangular annular shape in this embodiment) with or without ends having four sides parallel to the peripheral edges of the first principal surface 3. The single gate opening 94 may have an edge portion connecting the portion extending in the first direction X and the portion extending in the second direction Y in conformance to the gate wiring 52 (wiring upper portion 53) in plan view in an arcuate shape (preferably a quadrant arcuate shape).

Referring to FIG. 1, etc., the semiconductor device 1 includes a source pad electrode 95 disposed on the interlayer film 70. The source pad electrode 95 is a terminal electrode to which a source potential is externally applied. The source pad electrode 95 may be referred to as a “first pad electrode,” a “first principal surface electrode,” a “first terminal electrode,” etc. The source pad electrode 95 is disposed on a portion of the interlayer film 70 covering the active region 8. The source pad electrode 95 covers the plurality of gate electrodes 32 across the interlayer film 70, and is electrically separated from the plurality of gate electrodes 32 by the interlayer film 70. The source pad electrode 95 is electrically connected to the plurality of body regions 20, the outer body region 21, the plurality of source regions 23 and 24, the contact region 25, etc., through the plurality of source openings 90.

In this embodiment, the source pad electrode 95 includes a first pad portion 96, a second pad portion 97, and a third pad portion 98. The first pad portion 96 has a relatively large plane area, and forms a main body of the source pad electrode 95. In this embodiment, the first pad portion 96 is formed in a polygonal shape (a quadrangular shape in this embodiment) having four sides parallel to the peripheral edges of the chip 2 in plan view, and is shifted further to the fourth side surface 5D side with respect to a central portion of the active region 8. The first pad portion 96 covers the plurality of gate electrodes 32 across the interlayer film 70, and is electrically connected to the plurality of body regions 20, etc., through the plurality of source openings 90.

The second pad portion 97 has a plane area less than the plane area of the first pad portion 96, and is led out in a band shape (quadrangular shape) from one end portion (end portion on the first side surface 5A side) of the first pad portion 96 in the second direction Y toward the third side surface 5C. The second pad portion 97 covers the plurality of gate electrodes 32 across the interlayer film 70, and is electrically connected to the plurality of body regions 20, etc., through the plurality of source openings 90.

The third pad portion 98 has a plane area less than the plane area of the first pad portion 96, is led out in a band shape (quadrangular shape) from the other end portion (end portion on the second side surface 5B side) of the first pad portion 96 in the second direction Y toward the third side surface 5C, and faces the second pad portion 97 in the second direction Y. The third pad portion 98 covers the plurality of gate electrodes 32 across the interlayer film 70, and is electrically connected to the plurality of body regions 20, etc., through the plurality of source openings 90.

The plane area of the third pad portion 98 may be substantially equal to the plane area of the second pad portion 97. As a matter of course, the plane area of the third pad portion 98 may be larger than the plane area of the second pad portion 97, or may be less than the plane area of the second pad portion 97. Either or both of the second pad portion 97 and the third pad portion 98 may be used as a terminal portion for current monitoring.

The source pad electrode 95 does not necessarily have to include both the second pad portion 97 and the third pad portion 98 at the same time. The source pad electrode 95 may include only one of the second pad portion 97 and the third pad portion 98. As a matter of course, the source pad electrode 95 may be constituted of only the first pad portion 96, and does not have to include the second pad portion 97 and the third pad portion 98.

Referring to FIGS. 6 and 7, the source pad electrode 95 includes a first base electrode film 100 and a first principal electrode film 102. The first base electrode film 100 may be referred to as a “source base electrode film,” and the first principal electrode film 102 may be referred to as a “source principal electrode film.”

The first base electrode film 100 forms a lower layer portion of the source pad electrode 95 (the first pad portion 96, the second pad portion 97, and the third pad portion 98), and covers the interlayer film 70 in the active region 8. The first base electrode film 100 collectively covers a region of the interlayer film 70 where the plurality of source openings 90 are formed in a film shape. That is, the first base electrode film 100 enters into the plurality of source openings 90 from above the interlayer film 70.

The first base electrode film 100 has a portion covering an upper surface of the interlayer film 70 in a film shape and a portion covering the wall surfaces of the plurality of source openings 90 in a film shape. The first base electrode film 100 demarcates recesses in the plurality of source openings 90, respectively. The first base electrode film 100 may have a portion partially covering the gate wiring 52 across the interlayer film 70. The first base electrode film 100 may be formed at an interval inward from the gate wiring 52 in plan view.

Referring to FIG. 7, in this embodiment, the first base electrode film 100 has a laminated structure including a first electrode film 103 laminated on the interlayer film 70 and a second electrode film 104 laminated on the first electrode film 103. In this embodiment, the first electrode film 103 includes a Ti film, and the second electrode film 104 includes a TiN film.

The first base electrode film 100 does not necessarily have to have a laminated structure, and may have a single layer structure constituted of one of the first electrode film 103 (Ti film) and the second electrode film 104 (TiN film). A thickness of the first electrode film 103 may be 10 nm or more and 100 nm or less. A thickness of the second electrode film 104 may be 50 nm or more and 200 nm or less.

The first electrode film 103 collectively covers the region of the interlayer film 70 where the plurality of source openings 90 are formed in a film shape, and enters into the plurality of source openings 90 from above the interlayer film 70. The first electrode film 103 has a portion covering the upper surface of the interlayer film 70 in a film shape and a portion covering the wall surfaces of the plurality of source openings 90 in a film shape. The first electrode film 103 directly covers the interlayer film 70.

That is, the first electrode film 103 directly covers the second oxide film 73. The first electrode film 103 faces the plurality of gate electrodes 32 across the interlayer film 70.

The first electrode film 103 extends along the wall surface of the source opening 90 and covers the insulating film 31, the first oxide film 72, and the second oxide film 73. The first electrode film 103 faces the first electrode side portion 34 (second electrode side portion 35) of the gate electrode 32 across the interlayer film 70.

The first electrode film 103 covers the first principal surface 3 in a film shape at a bottom portion of each source opening 90, and is electrically connected to the first principal surface 3. Specifically, the first electrode film 103 has a portion covering the source recess 91 in a film shape at the bottom portion of each source opening 90, and is electrically connected to the plurality of source regions 23 and 24 and the contact region 25.

The first electrode film 103 may cover the source recess 91 in a film shape at an interval from a height position of the first principal surface 3 toward a bottom portion of the source recess 91. The first electrode film 103 may have a portion positioned on the bottom portion side of the source recess 91 with respect to the height position of the first principal surface 3, and a portion positioned on the insulating film 31 side with respect to the height position of the first principal surface 3.

The second electrode film 104 collectively covers the region of the interlayer film 70 where the plurality of source openings 90 are formed in a film shape on the first electrode film 103. The second electrode film 104 has a portion covering the upper surface of the interlayer film 70 in a film shape across the first electrode film 103, and a portion covering the wall surfaces of the plurality of source openings 90 in a film shape across the first electrode film 103. The second electrode film 104 faces the plurality of gate electrodes 32 across the first electrode film 103 and the interlayer film 70.

The second electrode film 104 extends along the wall surface of the source opening 90, and covers the insulating film 31, the first oxide film 72, and the second oxide film 73 across the first electrode film 103. The second electrode film 104 faces the first electrode side portion 34 (second electrode side portion 35) of the gate electrode 32 across the first electrode film 103 and the interlayer film 70.

The second electrode film 104 has a portion covering the source recess 91 in a film shape across the first electrode film 103 at the bottom portion of each source opening 90, and is electrically connected to the plurality of source regions 23 and 24 and the contact region 25 through the first electrode film 103. When the first electrode film 103 is positioned on the bottom portion side of the source recess 91 with respect to the first principal surface 3, the second electrode film 104 may have a portion positioned in the source recess 91. When the first electrode film 103 has a portion positioned above the first principal surface 3, the entire second electrode film 104 is positioned above the source recess 91.

The first principal electrode film 102 forms an upper layer portion of the source pad electrode 95 (the first pad portion 96, the second pad portion 97, and the third pad portion 98) and covers the first base electrode film 100 in a film shape. The first principal electrode film 102 contains a conductive material different from the conductive material of the first base electrode film 100.

The first principal electrode film 102 may include at least one among an Al film, an Al alloy film, a Cu film, and a Cu alloy film. The Al alloy film may include at least one among an AlSi alloy film, an AlCu alloy film, and an AlSiCu alloy film. The first principal electrode film 102 has a thickness larger than the thickness (total thickness) of the first base electrode film 100.

The thickness of the first principal electrode film 102 may be 0.5 μm or more and 5 μm or less. The thickness of the first principal electrode film 102 may have a value belonging to at least one range among 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less.

The first principal electrode film 102 enters into the plurality of source openings 90 from above the interlayer film 70, and is mechanically and electrically connected to the plurality of source regions 23 and 24 and the contact region 25. As a result, the first principal electrode film 102 faces the plurality of gate electrodes 32 across the first base electrode film 100 and the interlayer film 70. That is, the first principal electrode film 102 faces the electrode upper portion 33 and the electrode corner portion 41 of each gate electrode 32 across the first base electrode film 100 and the interlayer film 70.

The semiconductor device 1 includes a source finger electrode 110 led out from the source pad electrode 95 onto the outer peripheral region 9. The source finger electrode 110 transmits the source potential applied to the source pad electrode 95 to the outer peripheral region 9. In this embodiment, the source finger electrode 110 is routed from a portion of the source pad electrode 95 (first pad portion 96) on the fourth side surface 5D side onto a portion of the interlayer film 70 covering the outer peripheral region 9.

The source finger electrode 110 is led out above the terminal region 45, and is electrically connected to the terminal region 45 through the plurality of outer openings 92. Specifically, the source finger electrode 110 is electrically connected to the overlap region 46 of the terminal region 45 through the plurality of outer openings 92.

The source finger electrode 110 extends in a band shape along the terminal region 45 (overlap region 46). The source finger electrode 110 has a portion extending in a band shape in the first direction X and a portion extending in a band shape in the second direction Y in plan view. In this embodiment, the source finger electrode 110 is formed in a polygonal annular shape (in this embodiment, a quadrangular annular shape) having four sides parallel to the peripheral edges of the first principal surface 3, and surrounds the source pad electrode 95. The source finger electrode 110 may have an edge portion connecting the portion extending in the first direction X and the portion extending in the second direction Y in plan view in an arcuate shape (preferably a quadrant arcuate shape) (see FIG. 4).

Similarly to the source pad electrode 95, the source finger electrode 110 includes the first base electrode film 100 and the first principal electrode film 102. The first base electrode film 100 forms a lower layer portion of the source finger electrode 110, and covers the interlayer film 70 in the outer peripheral region 9.

The first base electrode film 100 collectively covers a region of the interlayer film 70 where the plurality of outer openings 92 are formed in a film shape. That is, the first base electrode film 100 enters into the plurality of outer openings 92 from above the interlayer film 70. The first base electrode film 100 has a portion covering the upper surface of the interlayer film 70 in a film shape and a portion covering the wall surfaces of the plurality of outer openings 92 in a film shape. The first base electrode film 100 demarcates recesses in the plurality of outer openings 92, respectively.

Similarly to the source pad electrode 95, the first base electrode film 100 has a laminated structure including the first electrode film 103 and the second electrode film 104. The first electrode film 103 collectively covers the region of the interlayer film 70 where the plurality of outer openings 92 are formed in a film shape, and enters into the plurality of outer openings 92 from above the interlayer film 70. That is, the first electrode film 103 has a portion covering the upper surface of the interlayer film 70 in a film shape and a portion covering the wall surfaces of the plurality of outer openings 92 in a film shape.

The first electrode film 103 covers the first principal surface 3 in a film shape at a bottom portion of each outer opening 92, and is electrically connected to the first principal surface 3 (chip 2). Specifically, the first electrode film 103 has a portion covering the outer recess 93 in a film shape at the bottom portion of each outer opening 92, and is electrically connected to the terminal region 45 (overlap region 46) in the outer recess 93.

The first electrode film 103 may cover the outer recess 93 in a film shape at an interval from the height position of the first principal surface 3 toward the bottom portion of the outer recess 93. The first electrode film 103 may have a portion positioned on the bottom portion side of the outer recess 93 with respect to the height position of the first principal surface 3, and a portion positioned on the outer peripheral insulating film 51 side with respect to the height position of the first principal surface 3.

The second electrode film 104 collectively covers the region of the interlayer film 70 where the plurality of outer openings 92 are formed in a film shape on the first electrode film 103. That is, the second electrode film 104 has a portion covering the upper surface of the interlayer film 70 in a film shape across the first electrode film 103, and a portion covering the wall surfaces of the plurality of outer openings 92 in a film shape across the first electrode film 103.

The second electrode film 104 has a portion covering the outer recess 93 in a film shape across the first electrode film 103 at the bottom portion of each outer opening 92, and is electrically connected to the terminal region 45 (overlap region 46) through the first electrode film 103. When the first electrode film 103 is positioned on the bottom portion side of the outer recess 93 with respect to the first principal surface 3, the second electrode film 104 may have a portion positioned in the outer recess 93. When the first electrode film 103 has a portion positioned above the first principal surface 3, the entire second electrode film 104 is positioned above the outer recess 93.

The first principal electrode film 102 forms an upper layer portion of the source finger electrode 110 and covers the first base electrode film 100 in a film shape. The first principal electrode film 102 enters into the plurality of outer openings 92 from above the interlayer film 70, and is mechanically and electrically connected to the terminal region 45 (overlap region 46).

The semiconductor device 1 includes a gate finger electrode 115 selectively routed on the interlayer film 70. The gate finger electrode 115 transmits a gate potential to the gate wiring 52. The gate finger electrode 115 is routed on a portion of the interlayer film 70 covering the gate wiring 52 (that is, on the outer peripheral region 9), and is electrically connected to the gate wiring 52 through the plurality of gate openings 94.

The gate finger electrode 115 is disposed in a region between the source pad electrode 95 and the source finger electrode 110 at an interval from the source pad electrode 95 and the source finger electrode 110. The gate finger electrode 115 is disposed on the gate wiring 52 and extends in a band shape along the gate wiring 52. The gate finger electrode 115 has a portion extending in a band shape in the first direction X and a portion extending in a band shape in the second direction Y in plan view.

In this embodiment, the gate finger electrode 115 is formed in a band shape with ends having four sides parallel to the peripheral edges of the first principal surface 3, and surrounds the source pad electrode 95. The gate finger electrode 115 may have an edge portion connecting the portion extending in the first direction X and the portion extending in the second direction Y in plan view in an arcuate shape (preferably a quadrant arcuate shape) (see FIG. 4). The gate finger electrode 115 has a pair of open ends that allow the source finger electrode 110 to pass therethrough on the fourth side surface 5D side.

Referring to FIG. 9, the gate finger electrode 115 includes a second base electrode film 120 and a second principal electrode film 122. The second base electrode film 120 may be referred to as a “gate base electrode film,” and the second principal electrode film 122 may be referred to as a “gate principal electrode film.”

The second base electrode film 120 forms a lower layer portion of the gate finger electrode 115 and covers the interlayer film 70 in the outer peripheral region 9. The second base electrode film 120 collectively covers a region of the interlayer film 70 where the plurality of gate openings 94 are formed in a film shape. That is, the second base electrode film 120 enters into the plurality of gate openings 94 from above the interlayer film 70. The second base electrode film 120 has a portion covering the upper surface of the interlayer film 70 in a film shape and a portion covering the wall surfaces of the plurality of gate openings 94 in a film shape. The second base electrode film 120 demarcates a plurality of recesses in the plurality of gate openings 94, respectively.

The second base electrode film 120 has a laminated structure including a first electrode film 123 laminated on the interlayer film 70 and a second electrode film 124 laminated on the first electrode film 123. Preferably, the first electrode film 123 contains the same type of conductive material as the first electrode film 103 on the source side, and the second electrode film 124 contains the same type of conductive material as the second electrode film 104 on the source side. In this embodiment, the first electrode film 123 includes a Ti film, and the second electrode film 124 includes a TiN film.

The second base electrode film 120 does not necessarily have to have a laminated structure, and may have a single layer structure constituted of one of the first electrode film 123 (Ti film) and the second electrode film 124 (TiN film). The first electrode film 123 may have a thickness substantially equal to the thickness of the first electrode film 103 on the source side. The second electrode film 124 may have a thickness substantially equal to the thickness of the second electrode film 104 on the source side.

The first electrode film 123 collectively covers the region of the interlayer film 70 where the plurality of gate openings 94 are formed in a film shape, and enters into the plurality of gate openings 94 from above the interlayer film 70. That is, the first electrode film 123 has a portion covering the upper surface of the interlayer film 70 in a film shape and a portion covering the wall surfaces of the plurality of gate openings 94 in a film shape.

The first electrode film 123 covers the gate wiring 52 in a film shape at a bottom portion of each gate opening 94, and is electrically connected to the gate wiring 52. Specifically, the first electrode film 123 has a portion covering the wiring upper portion 53 of the gate wiring 52 in a film shape at the bottom portion of each gate opening 94, and is mechanically and electrically connected to the wiring upper portion 53.

The first electrode film 123 is mechanically connected to the wiring upper portion 53 at an interval inward from the wiring corner portion 61. That is, the first electrode film 123 is mechanically connected only to the wiring upper portion 53, and is not mechanically connected to the wiring corner portion 61. The first electrode film 123 is electrically connected to the wiring corner portion 61 through the wiring upper portion 53. As a matter of course, the first electrode film 123 (second base electrode film 120) may have a portion connected to the wiring corner portion 61.

The second electrode film 124 collectively covers the region of the interlayer film 70 where the plurality of gate openings 94 are formed in a film shape on the first electrode film 123. That is, the second electrode film 124 has a portion covering the upper surface of the interlayer film 70 in a film shape across the first electrode film 123, and a portion covering the wall surfaces of the plurality of gate openings 94 in a film shape across the first electrode film 123.

The second electrode film 124 has a portion covering the gate wiring 52 in a film shape across the first electrode film 123 at the bottom portion of each gate opening 94, and is electrically connected to the gate wiring 52 through the first electrode film 123. Specifically, the second electrode film 124 has a portion covering the wiring upper portion 53 of the gate wiring 52 in a film shape across the first electrode film 123, and is electrically connected to the wiring upper portion 53 through the first electrode film 123.

The second electrode film 124 is positioned on the wiring upper portion 53 at an interval inward from the wiring corner portion 61. That is, the second electrode film 124 faces only the wiring upper portion 53 across the first electrode film 123, and does not face the wiring corner portion 61. The second electrode film 124 is electrically connected to the wiring corner portion 61 through the first electrode film 123 and the wiring upper portion 53. As a matter of course, the second electrode film 124 may have a portion facing the wiring corner portion 61 across the first electrode film 123.

The second principal electrode film 122 forms an upper layer portion of the gate finger electrode 115 and covers the second base electrode film 120 in a film shape. The second principal electrode film 122 contains a conductive material different from the conductive material of the second base electrode film 120.

The second principal electrode film 122 may include at least one among an Al film, an Al alloy film, a Cu film, and a Cu alloy film. The Al alloy film may include at least one among an AlSi alloy film, an AlCu alloy film, and an AlSiCu alloy film. The second principal electrode film 122 preferably contains the same type of conductive material as the conductive material of the first principal electrode film 102. The second principal electrode film 122 may have a thickness substantially equal to the thickness of the first principal electrode film 102.

The second principal electrode film 122 enters into the plurality of gate openings 94 from above the interlayer film 70, and is mechanically and electrically connected to the wiring upper portion 53.

The semiconductor device 1 includes a gate pad electrode 130 disposed on the interlayer film 70. The gate pad electrode 130 is a terminal electrode to which a gate potential is externally applied. The gate pad electrode 130 may be referred to as a “second pad electrode,” a “second principal surface electrode,” a “second terminal electrode,” etc. The gate pad electrode 130 is disposed in a region between the source pad electrode 95 and the source finger electrode 110 at an interval from the source pad electrode 95 and the source finger electrode 110.

In this embodiment, the gate pad electrode 130 is disposed in a region on the third side surface 5C side with respect to the first pad portion 96, and is sandwiched between the second pad portion 97 and the third pad portion 98. That is, the gate pad electrode 130 faces the first pad portion 96 in the first direction X, and faces the second pad portion 97 and the third pad portion 98 in the second direction Y.

The gate pad electrode 130 is formed in a polygonal shape (a quadrangular shape in this embodiment) having four sides parallel to the peripheral edges of the chip 2 in plan view. The gate pad electrode 130 has a plane area less than a plane area of the source pad electrode 95 (first pad portion 96). The gate pad electrode 130 may have a plane area less than the plane area of the second pad portion 97 (third pad portion 98).

The gate pad electrode 130 is disposed on a portion covering the active region 8 and the outer peripheral region 9, and is connected to the gate finger electrode 115. The gate pad electrode 130 may cover the plurality of gate electrodes 32 across the interlayer film 70, or may cover the gate wiring 52 across the interlayer film 70.

Similarly to the gate finger electrode 115, the gate pad electrode 130 includes the second base electrode film 120 and the second principal electrode film 122. The second base electrode film 120 forms a lower layer portion of the gate pad electrode 130 and covers the interlayer film 70 in a film shape. Similarly to the gate finger electrode 115, the second base electrode film 120 has a laminated structure including the first electrode film 123 and the second electrode film 124. The first electrode film 123 covers the interlayer film 70 in a film shape, and the second electrode film 124 covers the first electrode film 123 in a film shape. The second principal electrode film 122 forms an upper layer portion of the gate pad electrode 130 and covers the second base electrode film 120 in a film shape.

The gate potential applied to the gate pad electrode 130 is applied to the gate wiring 52 through the gate finger electrode 115. The gate potential is transmitted to the plurality of gate electrodes 32 through a wiring path (current path) along the gate wiring 52. As a result, the plurality of gate electrodes 32 are turned on, and on/off of the plurality of channel regions 26 and 27 is controlled.

The semiconductor device 1 includes a drain pad electrode 140 covering the second principal surface 4. The drain pad electrode 140 is a terminal electrode to which a drain potential is externally applied. The drain pad electrode 140 may be referred to as a “third pad electrode,” a “third principal surface electrode,” a “third terminal electrode,” etc. The drain pad electrode 140 is electrically connected to the second semiconductor region 7. The drain pad electrode 140 may cover an entire region of the second principal surface 4 such as to be continuous with the peripheral edges (the first to fourth side surfaces 5A to 5D) of the second principal surface 4. The drain pad electrode 140 may partially cover the second principal surface 4 such as to expose a peripheral edge portion of the second principal surface 4.

A breakdown voltage that can be applied between the source pad electrode 95 and the drain pad electrode 140 (between the first principal surface 3 and the second principal surface 4) may be 500 V or more and 3000 V or less. The breakdown voltage may have a value belonging to at least one range among 500 V or more and 1000 V or less, 1000 V or more and 1500 V or less, 1500 V or more and 2000 V or less, 2000 V or more and 2500 V or less, and 2500 V or more and 3000 V or less.

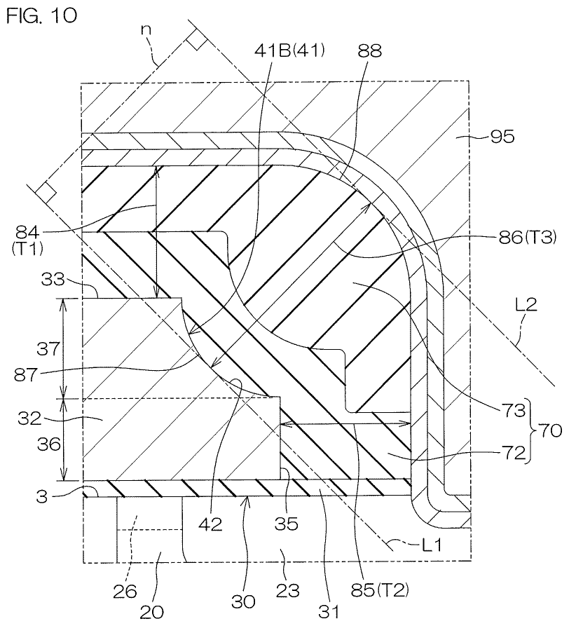

Next, the structures of the gate structure 30 and the interlayer film 70 will be described in detail with reference to FIG. 10. FIG. 10 is an enlarged cross-sectional view illustrating a main portion of FIG. 7, and shows the vicinity of the electrode corner portion 41 of the gate electrode 32 in an enlarged manner. In FIG. 10, a structure in the vicinity of the electrode corner portion 41B will be described, but the structure can also be applied to a structure in the vicinity of the electrode corner portion 41A and a structure in the vicinity of the wiring corner portions 61A and 61B.

As described above, the gate electrode 32 integrally includes the electrode upper portion 33, the electrode side portions 34 and 35, and the electrode corner portion 41. Thus, the gate electrode 32 is formed in a shape having a protrusion portion 37 that partially protrudes upward in cross-sectional view. For example, the gate electrode 32 may include a base portion 36 from a lower surface (a contact surface with the insulating film 31) of the gate electrode 32 to upper ends of the electrode side portions 34 and 35, and the protrusion portion 37 whose width is narrowed by the electrode corner portion 41 and which forms the electrode upper portion 33. In the vicinity of the electrode side portions 34 and 35 of the base portion 36, since the upper side is lacked due to the electrode corner portion 41 to form a space, a film thickness is selectively reduced. On the other hand, a region where the protrusion portion 37 is formed is a portion where the film thickness is selectively increased in the gate electrode 32.

In this embodiment, the protrusion portion 37 overlaps the first source region 23 and the first channel region 26. As a result, the thickness of the gate electrode 32 on the first channel region 26 can be increased. Therefore, even if the electrode corner portion 41 is formed, a resistance value of the gate electrode 32 can be kept small on the first channel region 26, so that a decrease in the responsiveness of the switching speed can be prevented.

The interlayer film 70 integrally includes an insulating upper portion 84 in contact with the electrode upper portion 33, an insulating side portion 85 in contact with the electrode side portions 34 and 35, and an insulating corner portion 86 in contact with the electrode corner portion 41.

The insulating upper portion 84 extends in a film shape in the horizontal direction along the electrode upper portion 33 and covers the electrode upper portion 33. The insulating side portion 85 rises vertically from the insulating film 31, extends in a film shape along the electrode side portions 34 and 35, and covers the electrode side portions 34 and 35.

The insulating corner portion 86 enters into the electrode corner portion 41 formed by a recess portion 42 curved toward the inner side of the gate electrode 32. More specifically, the insulating corner portion 86 has a first convex surface 87 that is curved toward the inner side of the gate electrode 32 along a curved surface of the recess portion 42, and a second convex surface 88 that is in contact with the source pad electrode 95 on the opposite side of the first convex surface 87 and is curved toward an obliquely upper part of the gate electrode 32. The insulating corner portion 86 has the first convex surface 87 and the second convex surface 88 that are curved in both directions away from each other in cross-sectional view. As a result, a thickness of the insulating corner portion 86 (corner portion thickness T3) is thicker than a thickness of the insulating upper portion 84 (upper portion thickness T1) and a thickness of the insulating side portion 85 (side portion thickness T2).

The corner portion thickness T3 may be, for example, a thickness of the interlayer film 70 in a normal direction n to both a first tangent L1 to the first convex surface 87 and a second tangent L2 to the second convex surface 88 parallel to the first tangent L1. In this embodiment, the upper portion thickness T1 and the side portion thickness T2 are, for example, 1000 Å or more and 5000 Å or less, and the corner portion thickness T3 is thicker than the upper portion thickness T1 and the side portion thickness T2. It suffices that the corner portion thickness T3 is thicker than the upper portion thickness T1 and the side portion thickness T2 in the total thickness of the interlayer film 70 including the first oxide film 72 and the second oxide film 73.

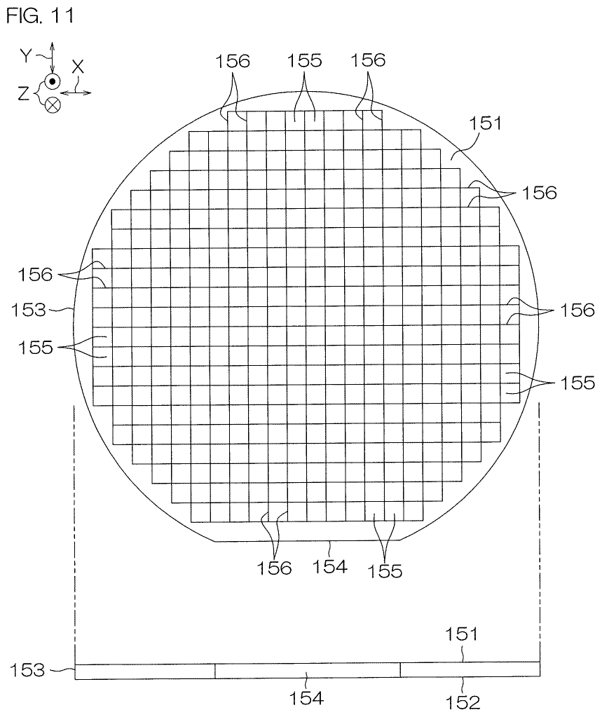

FIG. 11 is a schematic view illustrating a wafer 150 used for manufacturing the semiconductor device 1. Referring to FIG. 11, the wafer 150 is a base material of the chip 2 and includes an SiC monocrystal. The wafer 150 is formed in a flat disc shape. As a matter of course, the wafer 150 may be formed in a flat rectangular parallelepiped shape. The wafer 150 has a first wafer principal surface 151 on one side, a second wafer principal surface 152 on the other side, and a wafer side surface 153 connecting the first wafer principal surface 151 and the second wafer principal surface 152.

The first wafer principal surface 151 corresponds to the first principal surface 3 of the chip 2, and the second wafer principal surface 152 corresponds to the second principal surface 4 of the chip 2. The first wafer principal surface 151 and the second wafer principal surface 152 are formed by the c-plane of the SiC monocrystal. The first wafer principal surface 151 is formed by a silicon plane of the SiC monocrystal, and the second wafer principal surface 152 is formed by a carbon plane of the SiC monocrystal. The wafer 150 (the first wafer principal surface 151 and the second wafer principal surface 152) has the above-described off direction and off angle.

The wafer 150 has a mark 154 indicating a crystal orientation of the SiC monocrystal on the wafer side surface 153. The mark 154 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 151 in plan view.

The mark 154 may include either or both of a first orientation flat extending in the m-axis direction and a second orientation flat extending in the a-axis direction. The mark 154 may include either or both of an orientation notch recessed in the m-axis direction and an orientation notch recessed in the a-axis direction.

The wafer 150 includes the first semiconductor region 6 in a region (surface layer portion) on the first wafer principal surface 151 side. The first semiconductor region 6 is formed in a layer shape extending along the first wafer principal surface 151. In this embodiment, the first semiconductor region 6 consists of an epitaxial layer (specifically, an SiC epitaxial layer). The wafer 150 includes the second semiconductor region 7 in a region (surface layer portion) on the second wafer principal surface 152 side. The second semiconductor region 7 is formed in a layer shape extending along the second principal surface 4 and is electrically connected to the first semiconductor region 6. In this embodiment, the second semiconductor region 7 is constituted of a wafer main body (specifically, an SiC wafer). That is, in this embodiment, the wafer 150 is constituted of an epitaxial wafer (so-called epi-wafer) having a laminated structure including the wafer main body and the epitaxial layer.

For example, a plurality of device regions 155 and a plurality of intended cutting lines 156 are set in the wafer 150 by an alignment mark, etc. Each device region 155 is a region corresponding to the semiconductor device 1. The plurality of device regions 155 are each set in a quadrangular shape in plan view.

In this embodiment, the plurality of device regions 155 are set in a matrix along the first direction X and the second direction Y in plan view. The plurality of device regions 155 are each set at an interval inward from the peripheral edge of the first wafer principal surface 151 in plan view. The plurality of intended cutting lines 156 are set in a lattice extending along the first direction X and the second direction Y such as to demarcate the plurality of device regions 155.

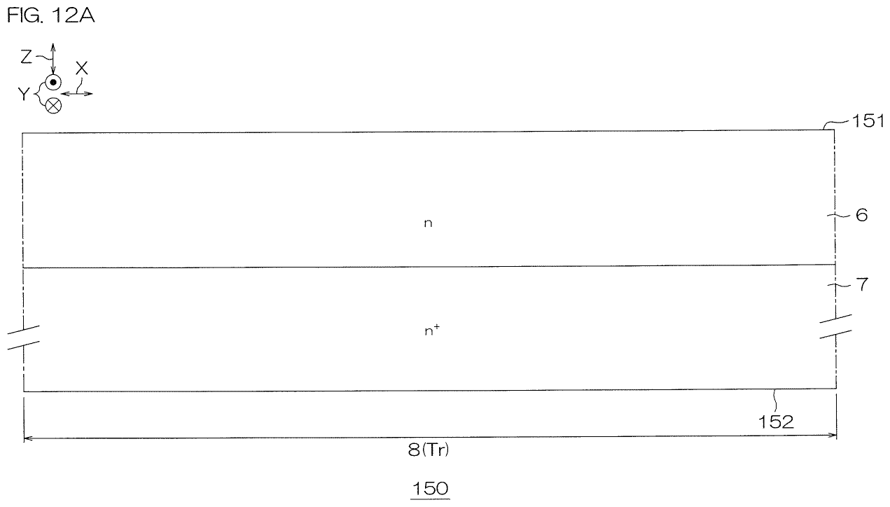

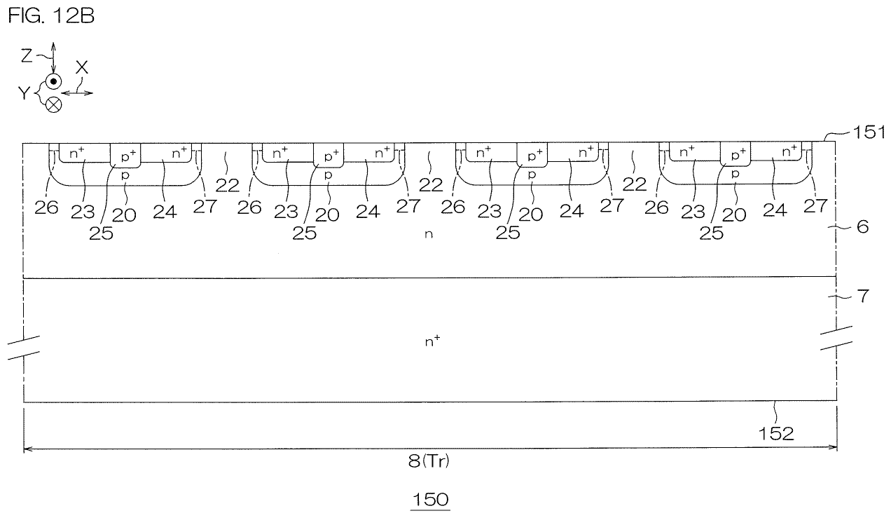

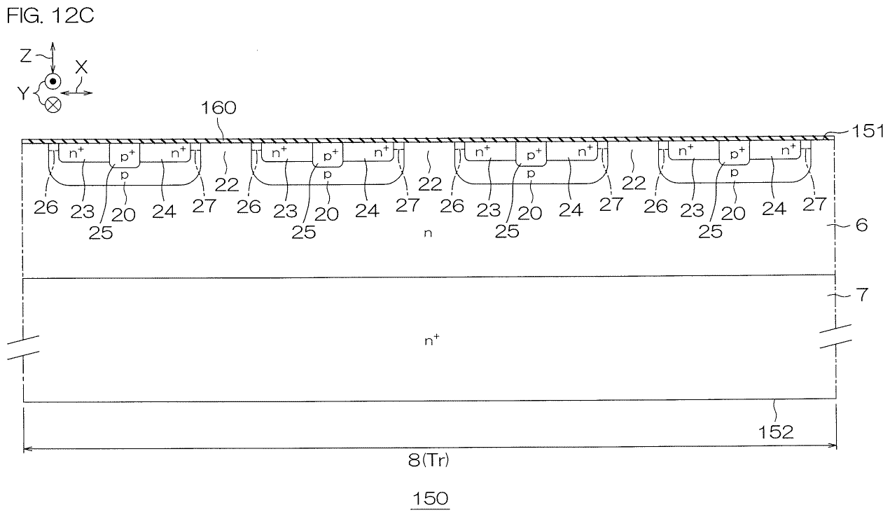

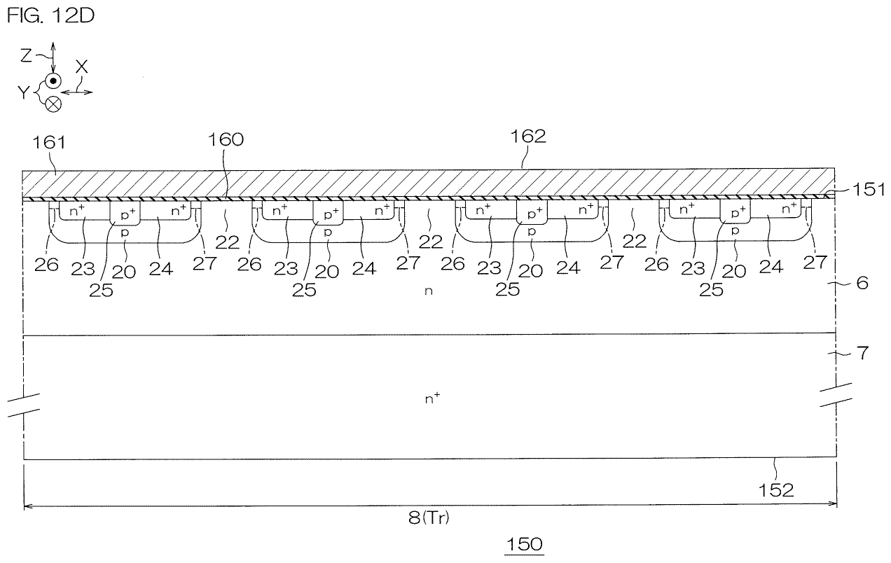

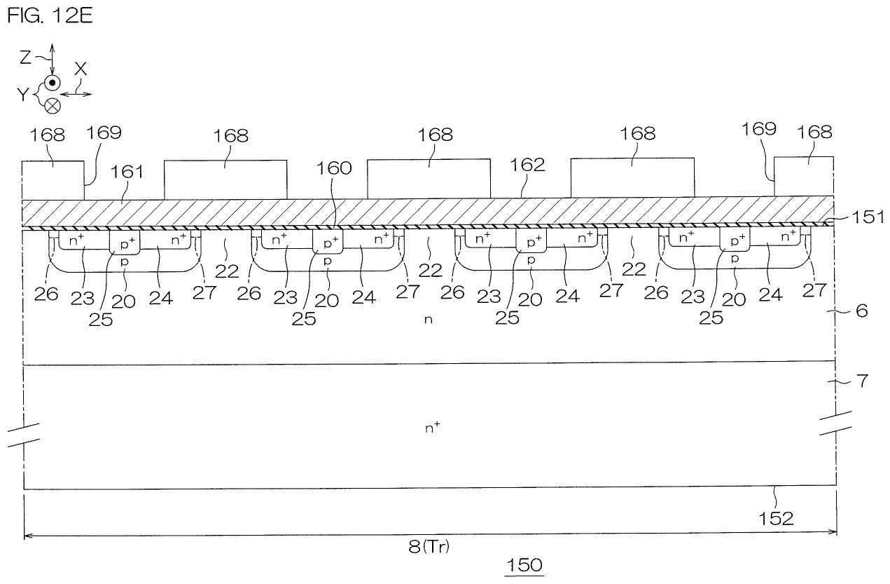

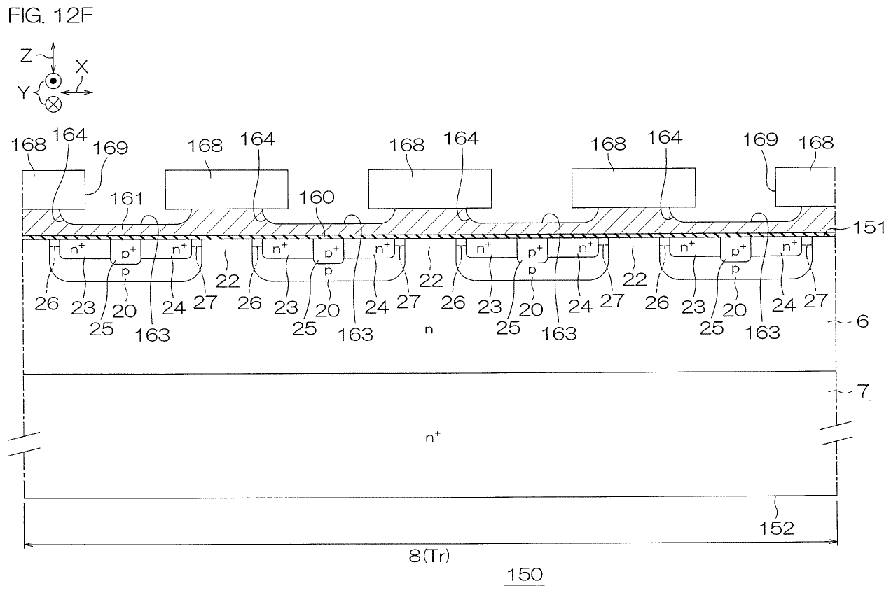

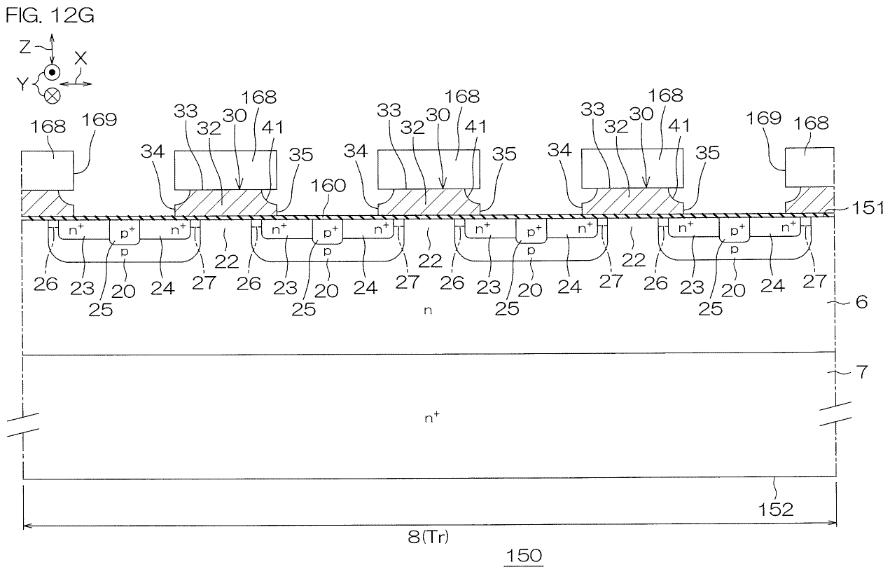

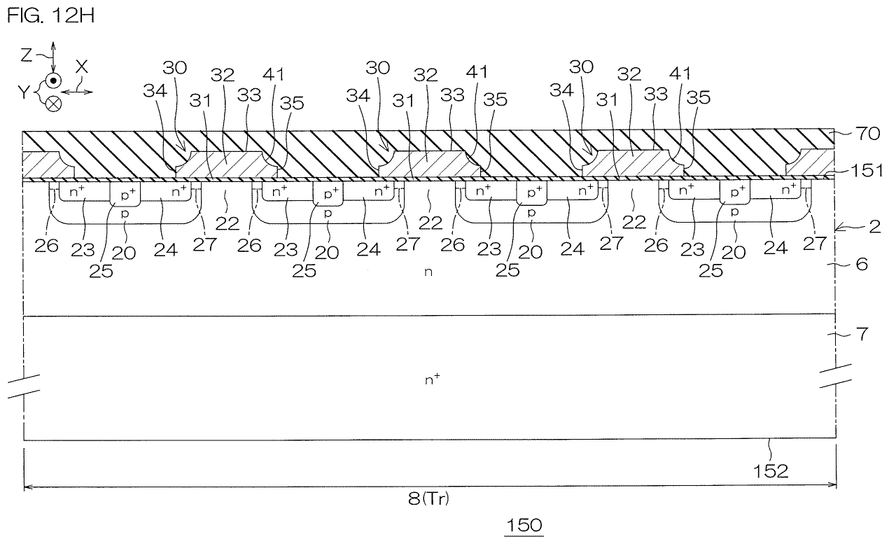

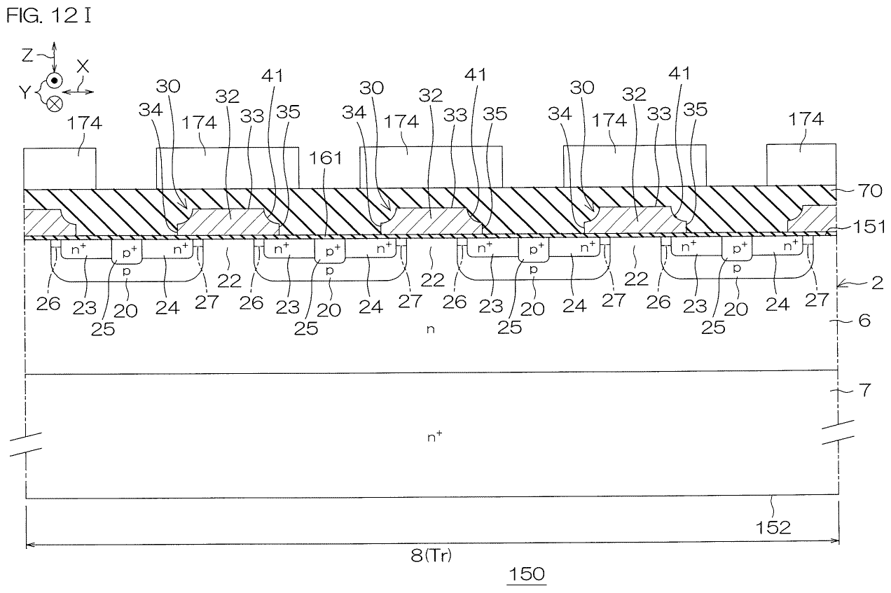

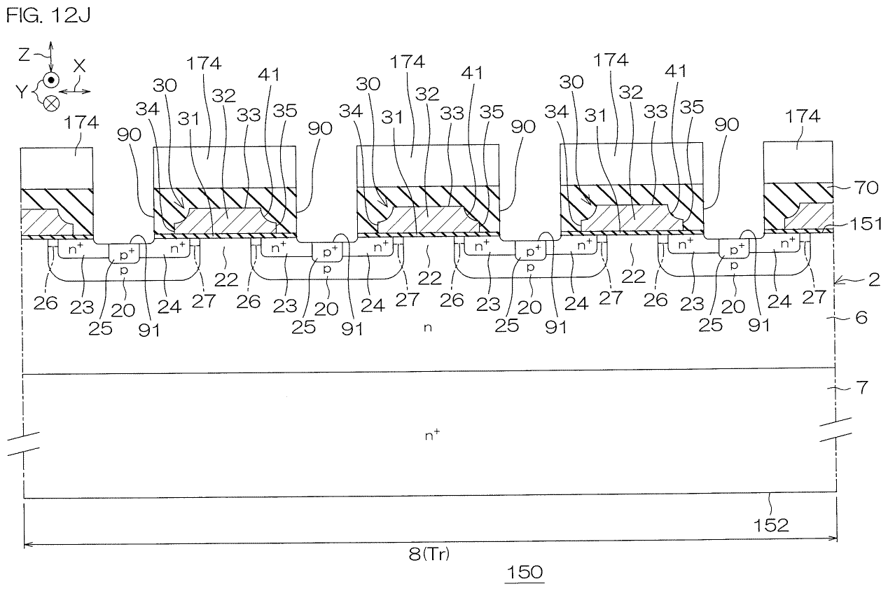

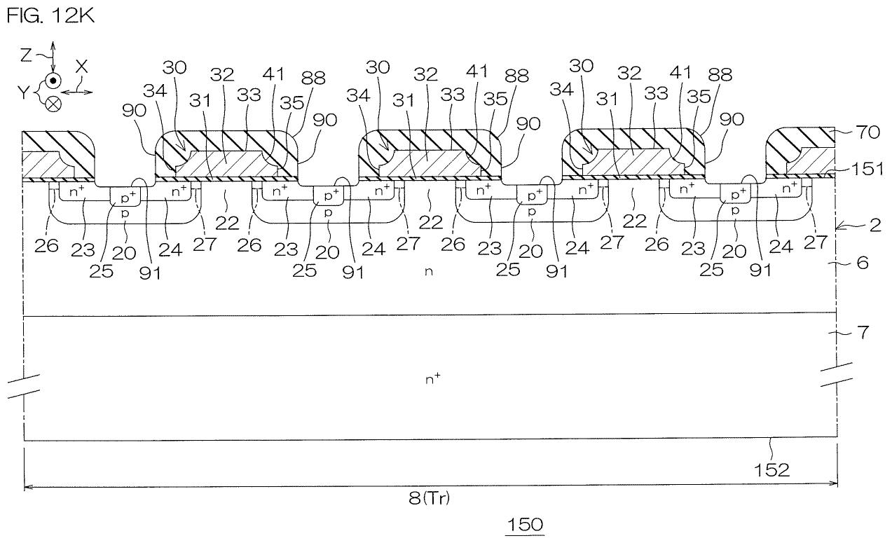

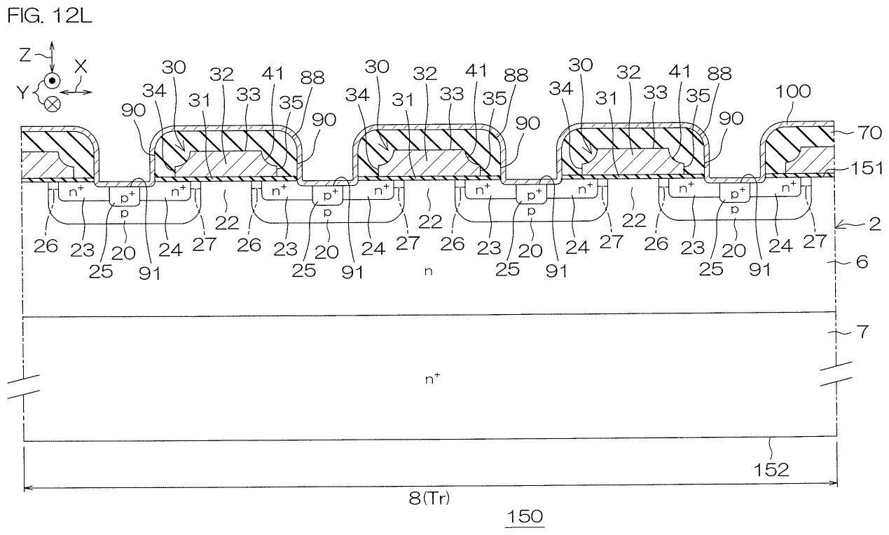

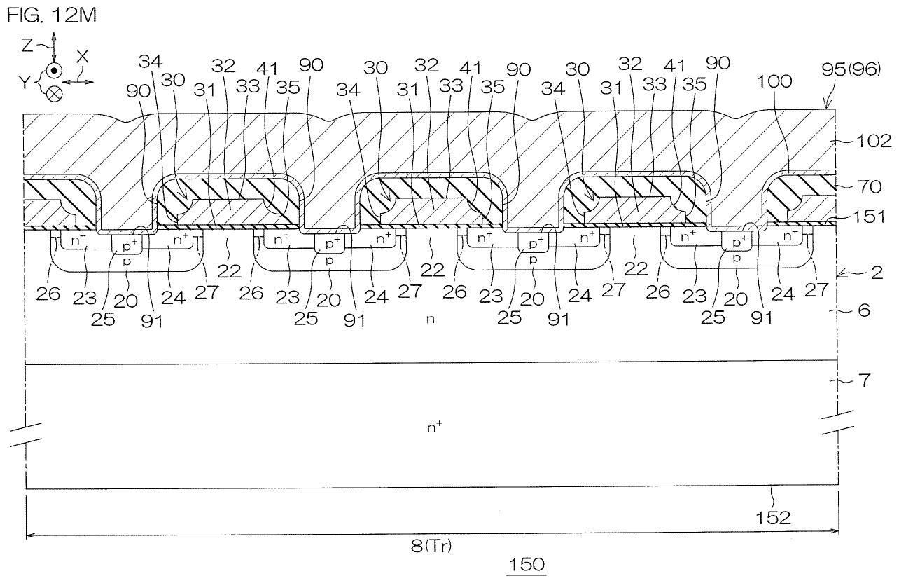

FIGS. 12A to 12M are cross-sectional views illustrating a method for manufacturing the semiconductor device 1. In FIGS. 12A to 12M, a cross-section of a portion of the active region 8 of one device region 155 is shown.

Referring to FIG. 12A, first, the above-described wafer 150 is prepared. Next, referring to FIG. 12B, a p-type impurity is selectively introduced into a surface layer portion of the first wafer principal surface 151 by an ion implantation method through a mask (not illustrated), and the plurality of body regions 20 are formed. In addition, a p-type impurity is selectively introduced into the surface layer portion of the first wafer principal surface 151 by the ion implantation method through a mask (not illustrated), and the outer body region 21 is formed. In addition, an n-type impurity is selectively introduced into the surface layer portion of the first wafer principal surface 151 by the ion implantation method through a mask (not illustrated), and the plurality of source regions 23 and 24 are formed.

In addition, a p-type impurity is selectively introduced into the surface layer portion of the first wafer principal surface 151 by the ion implantation method through a mask (not illustrated), and the plurality of contact regions 25 are formed. In addition, a p-type impurity is selectively introduced into the surface layer portion of the first wafer principal surface 151 by the ion implantation method through a mask (not illustrated), and the terminal region 45 is formed. In addition, a p-type impurity is selectively introduced into the surface layer portion of the first wafer principal surface 151 by the ion implantation method through a mask (not illustrated), and the plurality of field regions 47 are formed.

The order of a step of forming the body region 20, a step of forming the outer body region 21, a step of forming the source regions 23 and 24, a step of forming the contact region 25, a step of forming the terminal region 45, and a step of forming the field region 47 is arbitrary. The step of forming the outer body region 21 may be performed simultaneously with the step of forming the body region 20. The step of forming the field region 47 may be performed simultaneously with the step of forming the body region 20 or the step of forming the terminal region 45.

Next, referring to FIG. 12C, a base insulating film 160 covering the first wafer principal surface 151 is formed. The base insulating film 160 is a base of the insulating film 31 and the outer peripheral insulating film 51. The base insulating film 160 may be formed by a CVD (chemical vapor deposition) method or an oxidation treatment method (for example, a thermal oxidation treatment method).

Next, referring to FIG. 12D, a base electrode 161 is formed on the base insulating film 160. The base electrode 161 is a base of the gate electrode 32 and the gate wiring 52. The base electrode 161 contains a conductive polysilicon. The base electrode 161 may be formed by the CVD method. The base electrode 161 has a base electrode surface 162 extending along the base insulating film 160.

Next, referring to FIG. 12E, a mask 168 having a predetermined layout is formed on the base electrode 161 (base electrode surface 162). The mask 168 may be an organic mask (for example, a resist mask). The mask 168 has a plurality of openings 169 for exposing regions other than a plurality of mask portions covering regions where the plurality of gate electrodes 32 are to be formed.

The next step is an etching step of the base electrode 161. In this step, isotropic etching through the mask 168 is performed, followed by anisotropic etching. First, referring to FIG. 12F, the base electrode 161 is isotropically removed from the base electrode surface 162 in the thickness direction and the lateral direction by isotropic etching through the mask 168. Consequently, a recess portion 163 is formed immediately below the opening 169 in the base electrode 161. The recess portion 163 has recess corner portions 164 curved toward the inner side of the base electrode 161 at both end portions in the lateral direction along the first wafer principal surface 151.

Next, referring to FIG. 12G, the remaining portion of the base electrode 161 is removed in the thickness direction from a bottom surface of the recess portion 163 to the base insulating film 160 by anisotropic etching through the mask 168. As a result, the plurality of gate electrodes 32 each having the electrode upper portion 33, the electrode side portions 34 and 35, and the electrode corner portion 41 are formed. The arcuate electrode corner portion 41 is formed by the recess corner portion 164. In addition, the gate wiring 52 having the wiring upper portion 53, the wiring side portions 54 and 55, and the wiring corner portion 61 is formed. After the step of forming the gate electrode 32 and the gate wiring 52, the mask 168 is removed.

Next, referring to FIG. 12H, the interlayer film 70 is formed on the first wafer principal surface 151. In this step, the interlayer film 70 having a portion directly covering the electrode upper portion 33, the first electrode side portion 34, the second electrode side portion 35, and the electrode corner portion 41 of the gate electrode 32 is formed. In addition, the interlayer film 70 having a portion directly covering the wiring upper portion 53, the first wiring side portion 54, the second wiring side portion 55, and the wiring corner portion 61 of the gate wiring 52 is formed.

In this embodiment, the interlayer film 70 has a laminated structure including the first oxide film 72 and the second oxide film 73 (see FIG. 7). The first oxide film 72 includes a silicon oxide film that is not doped with an impurity. The second oxide film 73 includes a silicon oxide film containing phosphorus. The first oxide film 72 may be formed by the CVD method. The second oxide film 73 may be formed by the CVD method. After the step of forming the second oxide film 73, a reflow step (heat treatment step) is performed on the interlayer film 70. As a result, corner portions and front surface roughness of the interlayer film 70 are smoothed.

Next, referring to FIG. 12I, a mask 174 having a predetermined layout is disposed on the interlayer film 70. The mask 174 exposes regions where the plurality of source openings 90, the plurality of outer openings 92, and the plurality of gate openings 94 are to be formed, and covers regions other than them.

Next, referring to FIG. 12J, an unnecessary portion of the interlayer film 70 and an unnecessary portion of the base insulating film 160 are removed by an etching method through the mask 174. In this step, an unnecessary portion of the second oxide film 73, an unnecessary portion of the first oxide film 72, and an unnecessary portion of the base insulating film 160 are removed in this order. The etching method may be a wet etching method and/or a dry etching method. The etching method is preferably an anisotropic dry etching method (for example, an RIE (reactive ion etching) method).

As a result, the plurality of source openings 90, the plurality of outer openings 92, and the plurality of gate openings 94 are formed in the interlayer film 70. In addition, the insulating film 31 and the outer peripheral insulating film 51 are formed. This step may include a step of forming the plurality of source recesses 91 and a step of forming the plurality of outer recesses 93. In this case, a step of further digging portions of the first wafer principal surface 151 exposed from the plurality of source openings 90 and the plurality of outer openings 92 toward the second wafer principal surface 152 is performed. The mask 174 is then removed.

Next, referring to FIG. 12K, the second convex surface 88 curved toward the obliquely upper part of the gate electrode 32 is formed at an upper corner portion of the interlayer film 70 by a reflow process. A reflow condition is not particularly limited as long as the reflow condition is such that the upper corner portion of the interlayer film 70 that is pointed after etching in FIG. 12J becomes arcuate. For example, it may be appropriately determined according to the film thickness and film quality of the interlayer film 70, the opening width of the source opening 90, etc.

Next, referring to FIG. 12L, the first base electrode film 100 and the second base electrode film 120 are formed on the interlayer film 70. The first base electrode film 100 and the second base electrode film 120 may be formed by a sputtering method or a vapor deposition method.

Next, referring to FIG. 12M, the first principal electrode film 102 and the second principal electrode film 122 are formed on the first base electrode film 100 and the second base electrode film 120, respectively. The first principal electrode film 102 and the second principal electrode film 122 may include at least one among an Al film, an Al alloy film, a Cu film, and a Cu alloy film. The Al alloy film may include at least one among an AlSi alloy film, an AlCu alloy film, and an AlSiCu alloy film. The first principal electrode film 102 and the second principal electrode film 122 may be formed by the sputtering method or the vapor deposition method.

Thereafter, the drain pad electrode 140 is formed on the second wafer principal surface 152. The drain pad electrode 140 may be formed by the sputtering method or the vapor deposition method. Then, the wafer 150 is cut along the intended cutting line 156, and the plurality of semiconductor devices 1 are cut out. The semiconductor device 1 is manufactured through the steps including the above.

For example, the plurality of gate structures 30 may be arranged at a narrow pitch in order to meet a demand for size reduction of a device. Since a distance between the adjacent gate structures 30 is narrowed, if the interlayer film 70 is uniformly made thick to secure the withstand voltage, the width W of the source opening 90 for the source contact becomes very small. Reducing the width W of the source opening 90 reduces embeddability of a metal (source pad electrode 95) in the source opening 90. When the embeddability is deteriorated, voids form at the position of the source opening 90, and problems such as inflow of a plating solution and wire bonding failure (for example, insufficient strength at the time of wire bonding) occur. On the other hand, when the interlayer film 70 is thinned as a countermeasure for this problem, the film thickness of the insulating corner portion 86 cannot be sufficiently secured after reflow of the interlayer film 70, and insulation reliability between the gate and the source is lowered.

Therefore, according to the semiconductor device 1, since the electrode corner portion 41 is formed in the gate electrode 32, the corner portion thickness T3 of the interlayer film 70 can be selectively made thicker than the upper portion thickness T1 and the side portion thickness T2. As a result, after the source opening 90 is formed, the insulating corner portion 86 is formed in an arcuate shape like the second convex surface 88 by reflow, and even if the thickness becomes thinner than that before reflow (see FIG. 12K), the insulating corner portion 86 having a sufficient thickness can be secured on the electrode corner portion 41. Therefore, it is possible to meet the demand for narrowing the pitch of the gate structure 30 and improve the withstand voltage reliability. On the other hand, since the side portion thickness T2 can be formed relatively thin, formation of voids in the source opening 90 can be prevented.

In particular, in the case of the semiconductor device 1 including SiC, an extremely high voltage is applied due to its characteristics (physical properties) unlike a lateral type Si semiconductor device such as an LSI. Therefore, the semiconductor device 1 having appropriate electrical characteristics is provided by improving the insulation reliability between the gate and the source.

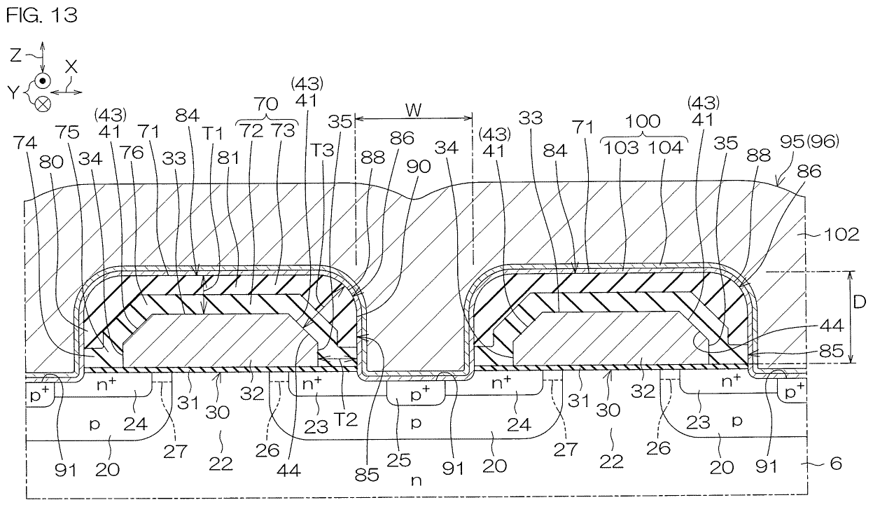

Hereinafter, a modification example of the gate electrode 32 will be described. FIG. 13 is a cross-sectional view illustrating a first modification example of the gate electrode 32.

Referring to FIG. 13, the electrode corner portion 41 of the gate electrode 32 does not necessarily have to be formed in an arcuate shape. For example, the electrode corner portion 41 may be formed by a flat inclined wall 43 inclined downward from the electrode upper portion 33 to the electrode side portions 34 and 35. The electrode corner portion 41 may be the flat inclined wall 43 inclined from the upper ends of the electrode side portions 34 and 35 toward the inside upward in the width direction of the gate electrode 32. In this case, the insulating corner portion 86 may have a flat surface 44 that is in contact with the inclined wall 43 and is inclined along the inclined wall 43.

Even when the electrode corner portion 41 is formed by the inclined wall 43, the thickness (corner portion thickness T3) of the insulating corner portion 86 can be made thicker than the thickness (upper portion thickness T1) of the insulating upper portion 84 and the thickness (side portion thickness T2) of the insulating side portion 85.

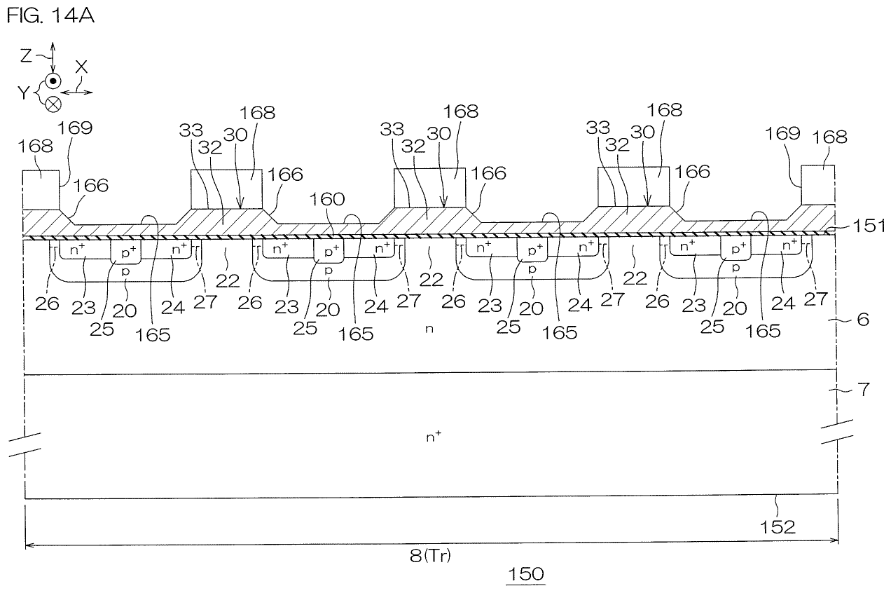

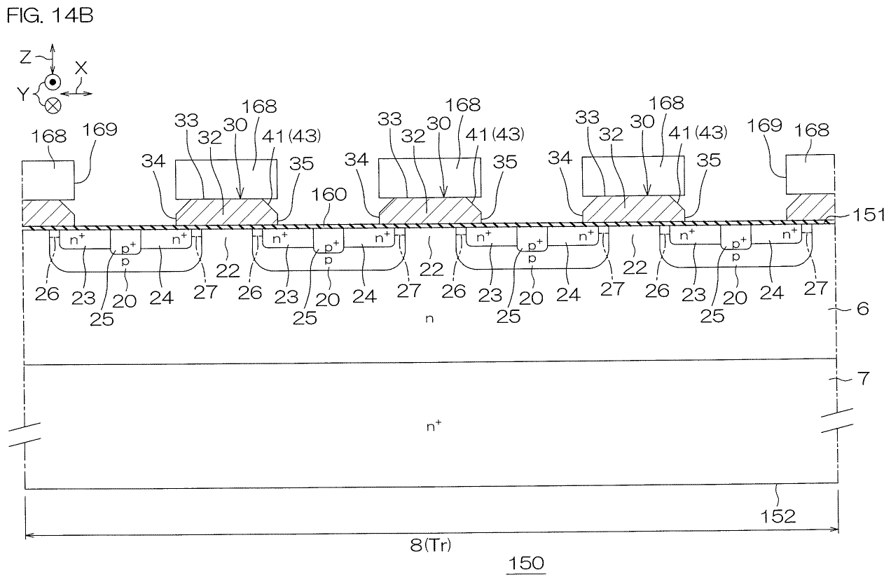

FIGS. 14A to 14B are views illustrating steps related to formation of the gate electrode 32 in FIG. 13.

Referring to FIG. 14A, in order to form the electrode corner portion 41 having the inclined wall 43, after the mask 168 is formed on the base electrode 161 (base electrode surface 162) (see FIG. 12E), the base electrode 161 is removed in a tapered shape in the thickness direction from the base electrode surface 162 by anisotropic taper etching through the mask 168. At this time, dry etching conditions may be appropriately set so that the base electrode 161 is etched in an oblique direction rather than a vertical direction. Consequently, a recess portion 165 is formed immediately below the opening 169 in the base electrode 161. The recess portion 165 has a recess corner portion 166 formed by a flat inclined wall inclined obliquely upward of the base electrode 161 at both end portions in the lateral direction along the first wafer principal surface 151.

Next, referring to FIG. 14B, the remaining portion of the base electrode 161 is removed in the thickness direction from a bottom surface of the recess portion 165 to the base insulating film 160 by anisotropic vertical etching through the mask 168. As a result, the plurality of gate electrodes 32 each having the electrode upper portion 33, the electrode side portions 34 and 35, and the electrode corner portion 41 (inclined wall 43) are formed. The inclined wall 43 of the electrode corner portion 41 is formed by the recess corner portion 166.

Thereafter, the steps of FIGS. 12H to 12M are performed to obtain the semiconductor device 1 illustrated in FIG. 13.

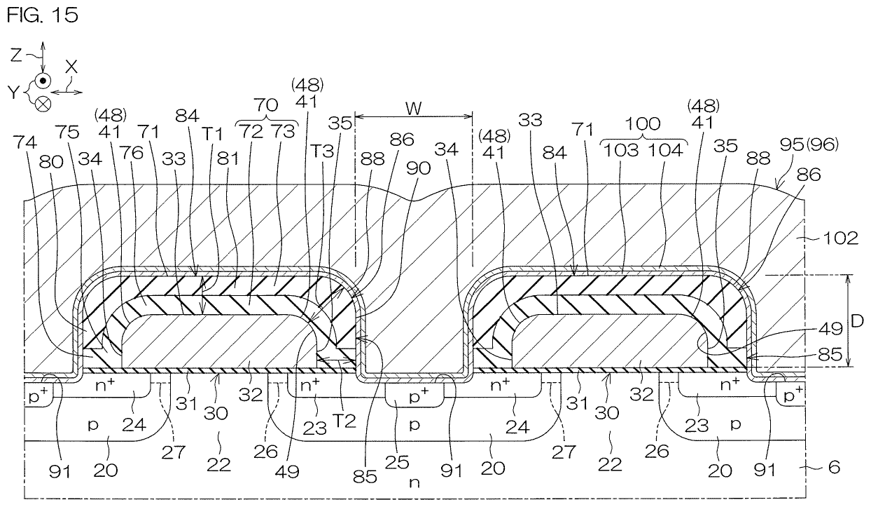

FIG. 15 is a cross-sectional view illustrating a second modification example of the gate electrode. Referring to FIG. 15, the electrode corner portion 41 of the gate electrode 32 does not necessarily have to be formed in an arcuate shape. For example, the electrode corner portion 41 may be formed by a round portion 48 connecting the electrode upper portion 33 and the electrode side portions 34 and 35 in an arcuate shape curved toward the obliquely upper part of the gate electrode 32. In this case, the insulating corner portion 86 may have a concave surface 49 that is in contact with the round portion 48 and formed in an arcuate shape along the round portion 48. The concave surface 49 is a surface curved in the same direction as the second convex surface 88 of the insulating corner portion 86.

Even when the electrode corner portion 41 is formed by the round portion 48, the thickness (corner portion thickness T3) of the insulating corner portion 86 can be made thicker than the thickness (upper portion thickness T1) of the insulating upper portion 84 and the thickness (side portion thickness T2) of the insulating side portion 85.

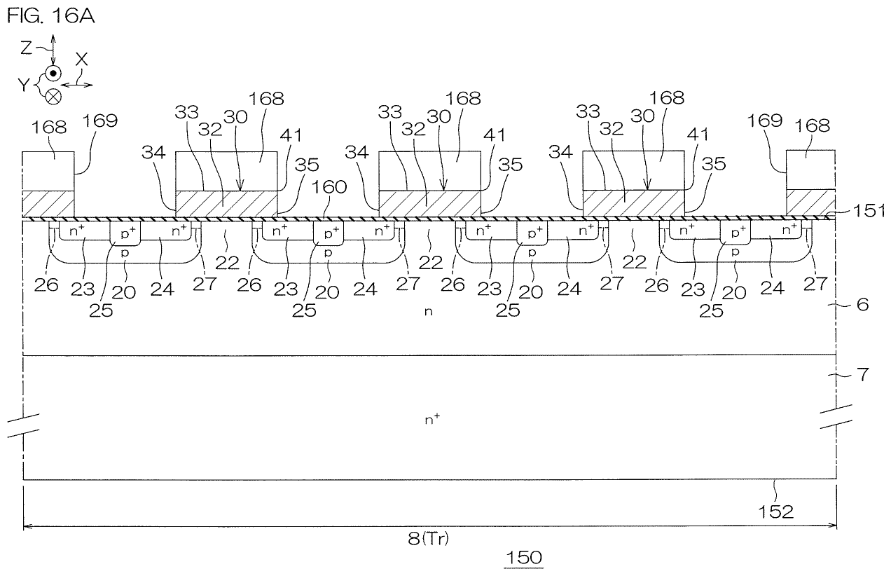

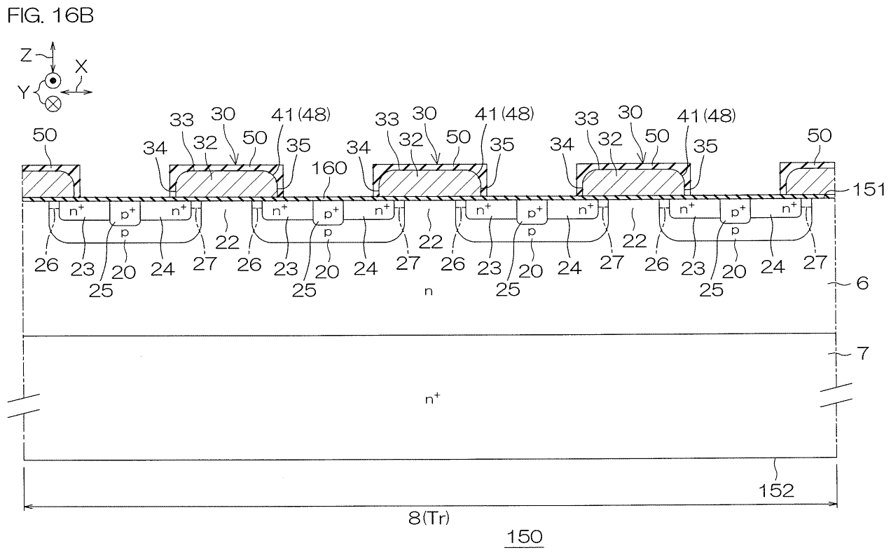

FIGS. 16A to 16B are views illustrating steps related to formation of the gate electrode 32 in FIG. 15.

Referring to FIG. 16A, in order to form the electrode corner portion 41 having the round portion 48, after the mask 168 is formed on the base electrode 161 (base electrode surface 162) (see FIG. 12E), the base electrode 161 is removed in the thickness direction from the base electrode surface 162 to the base insulating film 160 by anisotropic etching through the mask 168. As a result, the plurality of gate electrodes 32 with the electrode corner portions 41 pointed are formed.

Next, referring to FIG. 16B, a thermal oxide film 50 is formed on the front surface of the gate electrode 32 by a thermal oxidation treatment. The thermal oxidation of the gate electrode 32 proceeds in the vertical direction (longitudinal direction) from the electrode upper portion 33 and proceeds in the horizontal direction (lateral direction) from the electrode side portions 34 and 35. In the electrode corner portion 41, the thermal oxidation proceeds from both the longitudinal direction and the lateral direction, whereby the pointed corner of the electrode corner portion 41 is oxidized and lacked, and the arcuate round portion 48 is formed.

Thereafter, the steps of FIGS. 12H to 12M are performed to obtain the semiconductor device 1 illustrated in FIG. 13.

Although the preferred embodiments of the present disclosure have been described above, the semiconductor device 1 of the present disclosure can be implemented in other embodiments.

For example, in each of the above-described preferred embodiments, a configuration in which a relationship between the a-axis direction and the m-axis direction is interchanged may be adopted. A specific configuration in this case can be obtained by interchanging the “a-axis direction (off direction)” and the “m-axis direction (direction orthogonal to off direction)” in the above description and the accompanying drawings.

In each of the above-described preferred embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and the accompanying drawings.

In each of the above-described preferred embodiments, the chip 2 (the first semiconductor region 6 and the second semiconductor region 7) containing an SiC monocrystal is adopted. However, the chip 2 (the first semiconductor region 6 and the second semiconductor region 7) may include a monocrystal of a wide bandgap semiconductor other than the SiC monocrystal. The wide bandgap semiconductor is a semiconductor having a bandgap greater than a bandgap of silicon. Examples of the monocrystal of the wide bandgap semiconductor include gallium nitride, diamond, gallium oxide, etc. As a matter of course, the chip 2 (the first semiconductor region 6 and the second semiconductor region 7) may contain a silicon monocrystal.

In each of the above-described preferred embodiments, the second semiconductor region 7 of the “n-type” has been illustrated. However, the p-type second semiconductor region 7 may be adopted instead of the n-type second semiconductor region 7. In this case, an IGBT (insulated gate bipolar transistor) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The second semiconductor region 7 of the p-type may be an impurity region that contains a p-type impurity introduced into a surface layer portion of the second principal surface 4 of the chip 2 by the ion implantation method.

Hereinafter, examples of features extracted from this description and the attached drawings shall be indicated. Hereinafter, the alphanumeric characters, etc., in parentheses represent the corresponding components, etc., in the preferred embodiments described above, but are not intended to limit the scope of each clause to the preferred embodiments. The “semiconductor device” in the following clauses may be replaced with an “SiC semiconductor device,” a “wide bandgap semiconductor device,” a “semiconductor switching device,” a “MISFET device,” an “IGBT device,” etc., as needed.

### Appendix 1-1

A semiconductor device (1), including:
a chip (2) having a principal surface (3);
a gate electrode (32) formed on the principal surface (3), the gate electrode (32) including an electrode upper portion (33) along the principal surface (3), an electrode side portion (34, 35) rising from the principal surface (3), and an electrode corner portion (41) formed by lacking a part of a material of the gate electrode (32) and connecting the electrode upper portion (33) and the electrode side portion (34, 35);
an interlayer film (70) covering the gate electrode (32);
an opening (90) formed in the interlayer film (70) such as to be separated from the electrode side portion (34, 35) in a lateral direction along the principal surface (3) and exposing a part of the principal surface (3) as a contact surface; and
a front surface electrode (95) formed on the interlayer film (70) and mechanically and electrically connected to the contact surface in the opening (90),
wherein the interlayer film (70) includes an insulating upper portion (84) in contact with the electrode upper portion (33), an insulating side portion (85) in contact with the electrode side portion (34, 35), and an insulating corner portion (86) in contact with the electrode corner portion (41), and
a corner portion thickness (T3) of the interlayer film (70) at the insulating corner portion (86) is thicker than at least one of an upper portion thickness (T1) of the interlayer film (70) at the insulating upper portion (84) and a side portion thickness (T2) of the interlayer film (70) at the insulating side portion (85).

For example, in order to meet a demand for size reduction of a device, the plurality of gate electrodes (32) may be arranged at a narrow pitch. Since a distance between the adjacent gate electrodes (32) is narrowed, if the interlayer film (70) is uniformly made thick to secure a withstand voltage, a width of the opening (90) that exposes the contact surface becomes very small. Reducing the width of the opening (90) reduces embeddability of a metal in the opening (90). When the embeddability is deteriorated, voids form at the position of the opening (90), and problems such as inflow of a plating solution and wire bonding failure (for example, insufficient strength at the time of wire bonding) occur. On the other hand, when the interlayer film (70) is thinned as a countermeasure for this problem, a film thickness of the insulating corner portion (86) cannot be sufficiently secured after reflow of the interlayer film (70), and insulation reliability is deteriorated.

Therefore, according to this embodiment, since the electrode corner portion (41) is formed in the gate electrode (32) by lacking a part of the material of the gate electrode (32), the corner portion thickness (T3) of the interlayer film (70) can be selectively made thicker than the upper portion thickness (T1) and the side portion thickness (T2). As a result, even if the insulating corner portion (86) becomes thinner than that before reflow after the formation of the opening (90), the insulating corner portion (86) having a sufficient thickness can be secured on the electrode corner portion (41). Therefore, it is possible to meet the demand for narrowing the pitch of the gate electrode (32) and improve withstand voltage reliability. On the other hand, since the side portion thickness (T2) can be formed relatively thin, formation of voids in the opening (90) can be prevented.

### Appendix 1-2

The semiconductor device (1) according to Appendix 1-1, wherein the electrode corner portion (41) includes an arcuate recess portion (42) curved toward an inner side of the gate electrode (32).

### Appendix 1-3

The semiconductor device (1) according to Appendix 1-2, wherein the insulating corner portion (86) has a first convex surface (87) curved toward the inner side of the gate electrode (32) along a curved surface of the recess portion (42), and
the corner portion thickness (T3) includes a thickness of the interlayer film (70) in a normal direction (n) to a tangent (L1) to the first convex surface (87).

### Appendix 1-4

The semiconductor device (1) according to Appendix 1-2, wherein the insulating corner portion (86) includes a first convex surface (87) that is curved toward the inner side of the gate electrode (32) along the curved surface of the recess portion (42), and a second convex surface (88) that is in contact with the front surface electrode (95) on an opposite side of the first convex surface (87) and is curved toward an obliquely upper part of the gate electrode (32), and
the corner portion thickness (T3) includes a thickness of the interlayer film (70) in a normal direction (n) to both a first tangent (L1) to the first convex surface (87) and a second tangent (L2) to the second convex surface (88) parallel to the first tangent (L1).

### Appendix 1-5

The semiconductor device (1) according to Appendix 1-1, wherein the electrode corner portion (41) includes a flat inclined wall (43) inclined downward from the electrode upper portion (33) to the electrode side portion (34, 35).

### Appendix 1-6

The semiconductor device (1) according to Appendix 1-1, wherein the electrode corner portion (41) includes a round portion (48) connecting the electrode upper portion (33) and the electrode side portion (34, 35) in an arcuate shape curved toward the obliquely upper part of the gate electrode (32).

### Appendix 1-7

The semiconductor device (1) according to any one of Appendix 1-1 to Appendix 1-6, further including the plurality of gate electrodes (32) arranged at intervals on the principal surface (3),
wherein the opening (90) is demarcated in a region between the plurality of gate electrodes (32).

### Appendix 1-8

The semiconductor device (1) according to any one of Appendix 1-1 to Appendix 1-7, wherein the opening (90) has a vertically long aspect ratio (D/W) along a depth direction of the opening (90), and
the corner portion thickness (T3) is thicker than both the upper portion thickness (T1) and the side portion thickness (T2).

### Appendix 1-9

The semiconductor device (1) according to any one of Appendix 1-1 to Appendix 1-8, wherein the upper portion thickness (T1) and the side portion thickness (T2) are 1000 Å or more and 5000 Å or less.

### Appendix 1-10

The semiconductor device (1) according to any one of Appendix 1-1 to Appendix 1-9, wherein a width of the opening (90) is 0.2 μm or more and 3 μm or less, and a depth of the opening (90) is 0.2 μm or more and 2 μm or less.

### Appendix 1-11

The semiconductor device (1) according to any one of Appendix 1-1 to Appendix 1-10, wherein the interlayer film (70) includes a first oxide film (72) that is not doped with an impurity and covers the gate electrode (32) and a second oxide film (73) that contains phosphorus and covers the first oxide film (72), and
the opening (90) penetrates through both the first oxide film (72) and the second oxide film (73).

### Appendix 1-12

The semiconductor device (1) according to any one of Appendix 1-1 to Appendix 1-11 further including:
a semiconductor region (6) of a first conductivity type formed in a surface layer portion of the principal surface (3);
a body region (20) of a second conductivity type formed in a surface layer portion of the semiconductor region (6);
an impurity region (23, 24) of the first conductivity type formed in a surface layer portion of the body region (20);
a channel (26, 27) formed in a region between the semiconductor region (6) and the impurity region (23, 24) in the surface layer portion of the body region (20); and
an insulating film (31) covering the channel (26, 27) on the principal surface (3) and sandwiched between the gate electrode (32) and the channel (26, 27),
wherein the opening (90) exposes a part of the impurity region (23, 24) to the contact surface, and
the front surface electrode (95) is electrically connected to the impurity region (23, 24) in the opening (90).

### Appendix 1-13

The semiconductor device (1) according to any one of Appendix 1-1 to Appendix 1-12, wherein the chip (2) is an SiC chip (2).

### Appendix 1-14

A method for manufacturing a semiconductor device (1) including:
a step of forming a base electrode (161) on a principal surface (151) of a wafer (150);
a step of forming a gate electrode (32) including an electrode upper portion (33) along the principal surface (151), an electrode side portion (34, 35) rising from the principal surface (151), and an electrode corner portion (41) connecting the electrode upper portion (33) and the electrode side portion (34, 35) and including an arcuate recess portion (42) curved toward an inner side of the base electrode (161) by selectively performing isotropic etching on the base electrode (161) in a thickness direction and subsequently performing anisotropic etching;
a step of forming an interlayer film (70) on the principal surface (151) such as to cover the gate electrode (32);
a step of forming an opening (90) for exposing a part of the principal surface (151) as a contact surface in the interlayer film (70) such as to be separated from the electrode side portion (34, 35) in a lateral direction along the principal surface (151); and
a step of forming a front surface electrode (95) on the interlayer film (70) such as to be mechanically and electrically connected to the contact surface in the opening (90).

### Appendix 1-15

A method for manufacturing a semiconductor device (1) including:
a step of forming a base electrode (161) on a principal surface (151) of a wafer (150);
a step of forming a gate electrode (32) including an electrode upper portion (33) along the principal surface (151), an electrode side portion (34, 35) rising from the principal surface (151), and an electrode corner portion (41) connecting the electrode upper portion (33) and the electrode side portion (34, 35) and including a flat inclined wall (43) inclined downward from the electrode upper portion (33) to the electrode side portion (34, 35) by selectively performing anisotropic taper etching on the base electrode (161) in a thickness direction and subsequently performing anisotropic vertical etching;
a step of forming an interlayer film (70) on the principal surface (151) such as to cover the gate electrode (32);
a step of forming an opening (90) for exposing a part of the principal surface (151) as a contact surface in the interlayer film (70) such as to be separated from the electrode side portion (34, 35) in a lateral direction along the principal surface (151); and
a step of forming a front surface electrode (95) on the interlayer film (70) such as to be mechanically and electrically connected to the contact surface in the opening (90).

### Appendix 1-16

A method for manufacturing a semiconductor device (1) including:
a step of forming a base electrode (161) containing a polysilicon on a principal surface (151) of a wafer (150);
a step of forming a gate electrode (32) including an electrode upper portion (33) along the principal surface (151), an electrode side portion (34, 35) rising from the principal surface (151), and an electrode corner portion (41) connecting the electrode upper portion (33) and the electrode side portion (34, 35) by selectively performing anisotropic etching on the base electrode (161) in a thickness direction;
a step of forming an arcuate round portion (48) curved toward an obliquely upper part of the gate electrode (32) at the electrode corner portion (41) by thermally oxidizing the gate electrode (32);
a step of forming an interlayer film (70) on the principal surface (151) such as to cover the gate electrode (32);
a step of forming an opening (90) for exposing a part of the principal surface (151) as a contact surface in the interlayer film (70) such as to be separated from the electrode side portion (34, 35) in a lateral direction along the principal surface (151); and
a step of forming a front surface electrode (95) on the interlayer film (70) such as to be mechanically and electrically connected to the contact surface in the opening (90).

### Appendix 1-17

The method for manufacturing a semiconductor device (1) according to any one of Appendix 1-14 to Appendix 1-16, including a step of forming a convex surface (88) curved toward the obliquely upper part of the gate electrode (32) at an upper corner portion of the opening (90) of the interlayer film (70) by a reflow process.

1. A semiconductor device, comprising:
a chip having a principal surface;
a gate electrode formed on the principal surface, the gate electrode including an electrode upper portion along the principal surface, an electrode side portion rising from the principal surface, and an electrode corner portion formed by lacking a part of a material of the gate electrode and connecting the electrode upper portion and the electrode side portion;
an interlayer film covering the gate electrode;
an opening formed in the interlayer film such as to be separated from the electrode side portion in a lateral direction along the principal surface and exposing a part of the principal surface as a contact surface; and
a front surface electrode formed on the interlayer film and mechanically and electrically connected to the contact surface in the opening,
wherein the interlayer film includes an insulating upper portion in contact with the electrode upper portion, an insulating side portion in contact with the electrode side portion and an insulating corner portion in contact with the electrode corner portion, and
a corner portion thickness of the interlayer film at the insulating corner portion is thicker than at least one of an upper portion thickness of the interlayer film at the insulating upper portion and a side portion thickness of the interlayer film at the insulating side portion.

2. The semiconductor device according to claim 1, wherein the electrode corner portion includes an arcuate recess portion curved toward an inner side of the gate electrode.

3. The semiconductor device according to claim 2, wherein the insulating corner portion has a first convex surface curved toward the inner side of the gate electrode along a curved surface of the recess portion, and
the corner portion thickness includes a thickness of the interlayer film in a normal direction to a tangent to the first convex surface.

4. The semiconductor device according to claim 2, wherein the insulating corner portion includes a first convex surface that is curved toward the inner side of the gate electrode along the curved surface of the recess portion, and a second convex surface that is in contact with the front surface electrode on an opposite side of the first convex surface and is curved toward an obliquely upper part of the gate electrode, and
the corner portion thickness includes a thickness of the interlayer film in a normal direction to both a first tangent to the first convex surface and a second tangent to the second convex surface parallel to the first tangent.

5. The semiconductor device according to claim 1, wherein the electrode corner portion includes a flat inclined wall inclined downward from the electrode upper portion to the electrode side portion.

6. The semiconductor device according to claim 1, wherein the electrode corner portion includes a round portion connecting the electrode upper portion and the electrode side portion in an arcuate shape curved toward the obliquely upper part of the gate electrode.

7. The semiconductor device according to claim 1, further comprising the plurality of gate electrodes arranged at intervals on the principal surface,
wherein the opening is demarcated in a region between the plurality of gate electrodes.

8. The semiconductor device according to claim 1, wherein the opening has a vertically long aspect ratio along a depth direction of the opening, and
the corner portion thickness is thicker than both the upper portion thickness and the side portion thickness.

9. The semiconductor device according to claim 1, wherein the upper portion thickness and the side portion thickness are 1000 Å or more and 5000 Å or less.

10. The semiconductor device according to claim 1, wherein a width of the opening is 0.2 μm or more and 3 μm or less, and a depth of the opening is 0.2 μm or more and 2 μm or less.

11. The semiconductor device according to claim 1, wherein the interlayer film includes a first oxide film that is not doped with an impurity and covers the gate electrode and a second oxide film that contains phosphorus and covers the first oxide film, and
the opening penetrates through both the first oxide film and the second oxide film.

12. The semiconductor device according to claim 1 further comprising:
a semiconductor region of a first conductivity type formed in a surface layer portion of the principal surface;
a body region of a second conductivity type formed in a surface layer portion of the semiconductor region;
an impurity region of the first conductivity type formed in a surface layer portion of the body region;
a channel formed in a region between the semiconductor region and the impurity region in the surface layer portion of the body region; and
an insulating film covering the channel on the principal surface and sandwiched between the gate electrode and the channel,
wherein the opening exposes a part of the impurity region to the contact surface, and
the front surface electrode is electrically connected to the impurity region in the opening.

13. The semiconductor device according to claim 1, wherein the chip is an SiC chip.

14. A method for manufacturing a semiconductor device comprising:
a step of forming a base electrode on a principal surface of a wafer;
a step of forming a gate electrode including an electrode upper portion along the principal surface, an electrode side portion rising from the principal surface, and an electrode corner portion connecting the electrode upper portion and the electrode side portion and including an arcuate recess portion curved toward an inner side of the base electrode by selectively performing isotropic etching on the base electrode in a thickness direction and subsequently performing anisotropic etching;
a step of forming an interlayer film on the principal surface such as to cover the gate electrode;
a step of forming an opening for exposing a part of the principal surface as a contact surface in the interlayer film such as to be separated from the electrode side portion in a lateral direction along the principal surface; and
a step of forming a front surface electrode on the interlayer film such as to be mechanically and electrically connected to the contact surface in the opening.

15. A method for manufacturing a semiconductor device comprising:
a step of forming a base electrode on a principal surface of a wafer;
a step of forming a gate electrode including an electrode upper portion along the principal surface, an electrode side portion rising from the principal surface, and an electrode corner portion connecting the electrode upper portion and the electrode side portion and including a flat inclined wall inclined downward from the electrode upper portion to the electrode side portion by selectively performing anisotropic taper etching on the base electrode in a thickness direction and subsequently performing anisotropic vertical etching;
a step of forming an interlayer film on the principal surface such as to cover the gate electrode;
a step of forming an opening for exposing a part of the principal surface as a contact surface in the interlayer film such as to be separated from the electrode side portion in a lateral direction along the principal surface; and
a step of forming a front surface electrode on the interlayer film such as to be mechanically and electrically connected to the contact surface in the opening.

16. A method for manufacturing a semiconductor device comprising:
a step of forming a base electrode containing a polysilicon on a principal surface of a wafer;
a step of forming a gate electrode including an electrode upper portion along the principal surface, an electrode side portion rising from the principal surface, and an electrode corner portion connecting the electrode upper portion and the electrode side portion by selectively performing anisotropic etching on the base electrode in a thickness direction;
a step of forming an arcuate round portion curved toward an obliquely upper part of the gate electrode at the electrode corner portion by thermally oxidizing the gate electrode;
a step of forming an interlayer film on the principal surface such as to cover the gate electrode;
a step of forming an opening for exposing a part of the principal surface as a contact surface in the interlayer film such as to be separated from the electrode side portion in a lateral direction along the principal surface; and
a step of forming a front surface electrode on the interlayer film such as to be mechanically and electrically connected to the contact surface in the opening.

17. The method of manufacturing a semiconductor device according to claim 14, comprising a step of forming a convex surface curved toward the obliquely upper part of the gate electrode at an upper corner portion of the opening of the interlayer film by a reflow process.
